(19) United States
(12) Patent Application Publication
(10) Pub. No.: US 2018/0309063 A1
(43) Pub. Date: Oct. 25, 2018

(54) OPTOELECTRONIC DEVICES CONTAINING BENZODITHIOPHENE BASED COMPOUNDS AND A SPECIAL LIGHT ABSORBER

(71) Applicant: MERCK PATENT GMBH, Darmstadt (DE)

(72) Inventors: Kentaro KAWATA, Saitama (JP); Tomohisa GOTO, Kanagawa (JP); Owen LOZMAN, Southampton (GB)

(73) Assignee: MERCK PATENT GMBH, DARMSTADT (DE)

(21) Appl. No.: 15/738,028

(22) PCT Filed: May 24, 2016
(86) PCT No.: PCT/EP2016/000857

§ 371 Date: Dec. 19, 2017

(30) Foreign Application Priority Data
Jun. 19, 2015 (EP) 15172861.5

(51) Int. Cl. H01L 51/00; H01L 51/42; C08G 61/12

(52) U.S. Cl. CPC H01L 51/0036; H01L 51/0043; H01L 51/4226; C08G 61/126; H01L 2251/306; C08G 2261/122; C08G 2261/91; C08G 2261/1426; C08G 2261/3223; C08G 2261/3243; C08G 2261/3246; C08G 2261/512; C08G 2261/1424

(57) ABSTRACT

The present invention relates to optoelectronic devices containing a light absorber which is at least in part inorganic, preferably a perovskite, and polymers (including homopolymers and co-polymers), oligomers or small molecules that are based on benzo[1,2-b:4,5-b′]dithiophene bearing electron withdrawing groups, especially solar cells comprising perovskites.

### FIELD OF THE INVENTION

The present invention relates to optoelectronic devices containing a light absorber which is at least in part inorganic, preferably a perovskite, and polymers (including homopolymers and co-polymers), oligomers or small molecules that are based on benzo[1,2-b:4,5-b′]dithiophene bearing electron withdrawing groups, especially solar cells comprising perovskites.

### BACKGROUND OF THE INVENTION

Optoelectronic devices comprising perovskites as light absorber e.g. perovskite solar cells (PSCs) have attracted a great deal of attention in the past few years. It was shown that PSCs show a high power conversion efficiency (PCE) and a potential low cost production. The high efficiency of PSCs has been ascribed to an unusually large carrier diffusion length within the perovskite layer despite its high visible light absorptivity with a direct bandgap transition. Low cost production may be possible because alkylammonium lead halide perovskites used as the active layer in such solar cells can be deposited through a simple solution process. Highly efficient solar cells can then be fabricated by carefully choosing appropriate electron and hole selective contact layers on either side of the active layer containing the perovskite. Several techniques to deposit the perovskite layer have been reported, out of which the one step deposition of a solution mixture of a metal halide such as lead iodide and an alkylammonium halide such as methylammonium iodide and the two step sequential method where a metal halide film is exposed to a alkylammonium halide solution, are the two most prominent examples. Both methods seem to give comparable performance and can be employed to fabricate solar cells with very similar device architectures.

It is generally believed that the hole selective layer that comprises a hole-transporting material (HTM) is seen as one of the major bottlenecks limiting the overall power conversion efficiency (PCE) of the perovskite solar cell and so far only few compounds have been shown to yield comparable performance to 2,2′,7,7′-tetrakis-(N,N′-di-4-methoxyphenylamine)-9,9′-spirobifluorene known as spiro-MeOTAD or SHT-263. Other well performing HTMs are based on poly(triarylamines) (PTAA) or poly(alkylthiophenes) such as poly(3-hexylthiophene)(P3HT).

Recently, several polymers and oligomers from the field of organic photovoltaics (OPV) have been shown to work in PSCs, although they did not perform as good as the above-mentioned reference materials (see for examples, Nature Photonics 2013, 7, 486). A few benzo[1,2-b:4,5-b′]dithiophene (BDT) based materials have been tested as HTM in PSCs (see for example, Adv. Energy Mater. 2015, 1401720; Chem. Commun. 2014, 50, 11196; Chem. Commun. 2014, 50, 14566; ChemPhysChem 2014, 15, 2595; Electrochimica Acta 2015, 151, 21) yet the resulting devices exhibited only low to moderate power conversion efficiencies.

Accordingly, there continues to be a demand for materials for further optimizing the performance of optoelectronic devices comprising a light-absorber, especially for optimizing PSCs.

Surprisingly, it has been found that materials which are based on benzo[1,2-b:4,5-b′]dithiophene (BDT) bearing electron withdrawing groups improve the properties of optoelectronic devices comprising a light absorber which is at least in part inorganic, especially of solar cells comprising perovskites (PSCs).

Polymers, oligomers and small molecules based on benzo[1,2-b:4,5-b′]dithiophene bearing electron withdrawing groups are already known in the art. However, their advantageous use in optoelectronic devices comprising a light absorber such as a perovskite was not reported so far.

Examples of such polymers, oligomers or molecules are described in U.S. Pat. No. 7,524,922, WO 2011/085004, WO 2011/131280, WO 2012/143077, WO 2012/156022, WO 2013/045014, WO 2013/135339, WO 2013/142835 and WO 2013/182264.

### SUMMARY OF THE INVENTION

The invention relates to an optoelectronic device comprising a light absorber which is at least in part inorganic, especially a metal halide perovskite, and a polymer, oligomer or a compound comprising at least one monomeric unit according to formula (I)

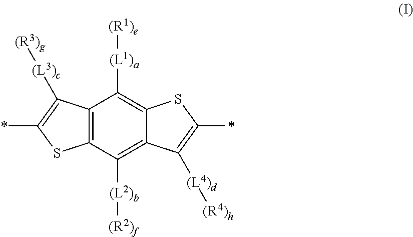

wherein
L¹⁻⁴ denote independently of each other, and on each occurrence identically or differently —C(═O)—, —C(═S)—, —C(═O)—O—, —C(═S)—O—, —C(═S)—S—, —C(═O)—S—, —O—C(═O)—, —O—C(═S)—, —C(═O)—NR⁰—, —NR⁰—C(O)—, —S(═O)(═O)—, —S(═O)(═O)—O—, —O—S(═O)(═O)—, —CF₂—, —CHF—, —CCl₂—, —CHCl—, —SF₄— or a terminal group —F, —Cl, —Br, —I, —NO₂, —SF₅, —CN, —NCO, —NCS, —OCN or —SCN in which case the respective e, f, g, h are defined as 0;
R¹⁻⁴ independently of each other denote H, halogen, straight-chain, branched or cyclic alkyl with 1 to 40 C atoms, in which one or more non-adjacent CH₂ groups are optionally replaced by —O—, —S—, —C(O)—, —C(O)—O—, —O—C(O)—, —O—C(O)—O—, —SO₂—, —SO₃—, —NR⁰—, —SiR⁰R⁰⁰—, —CF₂—, —CR⁰═CR⁰⁰—, —CY¹═CY²— or —C≡C— in such a manner that O and/or S atoms are not linked directly to one another, and in which one or more H atoms are optionally replaced by F, Cl, Br, I or CN, or
   aryl or heteroaryl having 4 to 30 ring atoms which are optionally substituted;
Y¹ and Y² independently of each other denote F, Cl or CN wherein one of Y¹ or Y² may additionally denote H;
R⁰⁻⁰⁰ independently of each other denote
   alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —Si(R*)₂—, —N(R*)₂—, —CR*═CR*— or —C≡C— such that O- and/or S-atoms are not directly linked to each other;
   aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
   or denote H;
R* independently of each other, and on each occurrence identically or differently denotes F, Cl, CN, straight-chain or branched alkyl with 1 to 20 C atoms, straight-chain or branched alkoxy with 1 to 20 C atoms, straight-chain or branched oxaalkyl with 1 to 12 C-atoms, straight-chain or branched thioalkyl with 1 to 12 C atoms, straight-chain or branched fluoroalkyl with 1 to 12 C atoms and straight-chain or branched fluoroalkoxy with 1 to 12 C atoms or straight-chain or branched alkenyl with 2 to 20 C atoms;
a-h are 0 or 1 and at least either a, b, c or d is 1.

The invention further relates to a multijunction device comprising at least one optoelectronic device comprising a light absorber which is at least in part inorganic and a polymer, oligomer or a compound comprising at least one monomeric unit according to formula (I) as described above.

The invention further relates to a module comprising at least one optoelectronic device comprising a light absorber which is at least in part inorganic and a polymer, oligomer or a compound comprising at least one monomeric unit according to formula (I) as described above.

The invention further relates to the use of a polymer, oligomer or a compound comprising at least one monomeric unit according to formula (I) as described above in optoelectronic devices comprising a light absorber which is at least in part inorganic.

### DETAILED DESCRIPTION OF THE INVENTION

The optoelectronic device according to the invention include, without limitation, a solar cell, an optical detector, a photoreceptor, a photodiode, a photomultiplier, a photo resistor, a photo detector, a lightsensitive detector, a solid-state triode, a transistor, an integrated circuit, a field-quench device, a light-emitting device, a laser, a laser diode, a plasmon emitting device, an electrophotography device or a wave converter.

The term solar cell is known in the art as a device converting any kind of light into electricity. The term solar cell includes a photovoltaic cell.

A transistor includes a phototransistor, a field-effect transistor, a thin-film transistor, a light-emitting transistor.

A light-emitting device includes an electroluminescent device, a photoluminescent device, a bioluminescent device and a light-emitting diode.

An electroluminescent device includes a light-emitting electrochemical cell.

A laser includes a diode injection laser.

The invention further relates to an optoelectronic device as described before which is a solar cell, an optical detector, a photoreceptor, a photodiode, a photomultiplier, a photo resistor, a photo detector, a lightsensitive detector, a solid-state triode, a transistor, an integrated circuit, a field-quench device, a light-emitting device, a laser, a laser diode, a plasmon emitting device, an electrophotography device or a wave converter.

The preferred optoelectronic device according to the invention is a solar cell.

The preferred optoelectronic device according to the invention is therefore a solar cell comprising the light absorber which is at least in part inorganic as described or preferably described below.

There are no restrictions per se with respect to the choice of the light absorber material which is at least in part inorganic in the optoelectronic device according to the invention.

The term “at least in part inorganic” means that the light absorber material may be selected from metalorganic complexes or materials which are substantially inorganic and possess preferably a crystalline structure where single positions in the crystalline structure may be allocated by organic ions.

Preferably, the light absorber comprised in the device according to the invention has an optical band-gap ≤2.8 eV and ≥0.8 eV.

Very preferably, the light absorber in the device according to the invention has an optical band-gap ≤2.2 eV and ≥1.0 eV.

The light absorber used in the device according to the invention does not comprise fullerenes. The chemistry of fullerenes belongs to the field of organic chemistry. Therefore fullerenes do not fulfil the definition of being “at least in part inorganic” according to the invention.

The light absorber which is at least in part inorganic is without limitation composed of a material having perovskite crystalline structure, a material having 2D crystalline perovskite structure (e.g. CrystEngComm, 2010, 12, 2646-2662), a metal halide, a chalcopyrite, a kesterite, a metal oxide or a mixture thereof.

The light absorber which is at least in part inorganic is without limitation composed of a material having perovskite crystalline structure, a material having 2D crystalline perovskite structure (e.g. CrystEngComm, 2010, 12, 2646-2662), Sb₂S₃(stibnite), Sb₂(SₓSe₍ₓ₋₁₎)₃, PbSₓSe₍ₓ₋₁₎, CdSₓSe₍ₓ₋₁₎, ZnTe, CdTe, ZnSₓSe₍ₓ₋₁₎, InP, FeS, FeS₂, Fe₂S₃, Fe₂SiS₄, Fe₂GeS₄, Cu₂S, CuInGa, CuIn(SeₓS₍₁₋ₓ₎)₂, Cu₃SbₓBi₍ₓ₋₁₎, (S_{y}Se_{(y-1)})₃, Cu₂SnS₃, (Methylammonium)₂Cu(ClₓBr₁₋ₓ)₄, SnSₓSe₍ₓ₋₁₎, Ag₂S, AgBiS₂, BiSI, BiSeI, Bi₂(SₓSe₍ₓ₋₁₎)₃, BiS₍₁₋ₓ₎SeₓI, ((Methylammonium)ₓCs₍₁₋ₓ₎)₃B₂I₉, MethylammoniumBiSCl₂, MethylammoniumBiSBr₂, MethylammoniumBiSI₂, MethylammoniumBiSeCl₂, MethylammoniumBiSeBr₂, MethylammoniumBiSeI₂, MethylammoniumBiTeC₂, MethylammoniumBiTeBr₂, MethylammoniumBiTeI₂, MethylammoniumBiAgCl₆, Cs₂BiCuCl₆, Cs₂BiCuBr₆, Cs₂BiCuI₆, Cs₂BiAgCl₆, Cs₂BiAgBr₆, Cs₂BiAgI₆, Cs₂BiAuCl₆, Cs₂BiAuBr₆, Cs₂BiAuI₆, Cs₂SbCuCI₆, Cs₂SbCuBr₆, Cs₂SbCuI₆, Cs₂SbAgCl₆, Cs₂SbAgBr₆, Cs₂SbAgI₆, Cs₂SbAuCl₆, Cs₂SbAuBr₆, Cs₂SbAuI₆, WSe₂, AlSb, CaZrS₃, BaZrS₃, CaZrSe₃, CaHfSe₃, metal halides (e.g. BiI₃, Cs₂SnI₆), chalcopyrite (e.g. CuInₓGa₍₁₋ₓ₎(S_{y}Se_{(1-y)})₂), kesterite (e.g. Cu₂ZnSnS₄, Cu₂ZnSn(SeₓS₍₁₋ₓ₎)₄, Cu₂Zn(Sn₁₋ₓGeₓ)S₄) and metal oxide (e.g. CuO, Cu₂O) or a mixture thereof.

In the above definition for light absorber, x and y are each independently defined as follows: (0≤x≤1) and (0≤y≤1).

Preferably, the light absorber which is at least in part inorganic is a material having perovskite structure or a material having 2D crystalline perovskite structure.

The term “perovskite” used within the description denotes generally a material having a perovskite crystalline structure or a 2D crystalline perovskite structure.

Therefore, the light absorber which is at least in part inorganic is preferably a perovskite.

The term perovskite solar cell (PSC) is a solar cell comprising a perovskite.

Very preferably, the light absorber is a special perovskite namely a metal halide perovskite as described in detail below. Most preferably, the light absorber is an organic-inorganic hybrid metal halide perovskite contained in the perovskite solar cell (PSC).

The invention therefore relates to an optoelectronic device as described before which is a solar cell.

The invention therefore relates to an optoelectronic device as described before which is a perovskite solar cell.

The PSC device architecture can for example be of any type known from the literature as described in detail below.

The invention further relates to the device as described or preferably described before wherein the polymer, oligomer or compound comprising at least one unit according to formula (I) is employed as a layer between one electrode and the light absorber layer.

The invention further relates to the device as described or preferably described before wherein the polymer, oligomer or compound comprising at least one unit according to formula (I) is comprised in a hole-selective layer.

The hole selective layer is defined as a layer providing a high hole conductivity and a low electron conductivity favorising hole-charge transport.

The invention further relates to the device as described or preferably described before wherein the polymer, oligomer or compound comprising at least one monomeric unit according to formula (I) is employed as hole transport material (HTM) or as electron blocking material as part of the hole selective layer.

Preferably, the polymer, oligomer or compound comprising at least one monomeric unit according to formula (I) is employed as hole transport material (HTM).

In an alternative preferred embodiment, the polymer, oligomer or compound comprising at least one monomeric unit according to formula (I) is employed as electron blocking material.

Within the following description, the abbreviation BDT means benzo[1,2-b:4,5-b′]dithiophene.

The above and below described or preferably described polymers, oligomers and compounds comprising at least one monomeric unit according to formula (I) demonstrate the following improved properties compared to previously disclosed BDT based hole transport materials (HTMs):

i) The electron withdrawing group(s) on the BDT core improve(s) the interfacial contact with the light absorber layer especially the perovskite layer in the optoelectronic device and/or ameliorates the charge transfer across the interfaces and therefore increases the device performance.
ii) The electron withdrawing group(s) on the BDT core improve the film wetting with the light absorber layer especially the perovskite layer in the optoelectronic device and therefore increases the device performance.
iii) Compared to previously reported polymer HTMs, the BDT based polymer, oligomer or compound according to the present invention do not need the use of dopant(s) and/or additive(s) to enable performance similar to the state of the art compound, namely spiro-OMeTAD.

The term “polymer” generally means a molecule of high relative molecular mass, the structure of which essentially comprises the multiple repetition of units derived, actually or conceptually, from molecules of low relative molecular mass (PAC, 1996, 68, 2291). The term “polymer” includes homopolymers and co-polymers. The term “oligomer” generally means a molecule of intermediate relative molecular mass, the structure of which essentially comprises a small plurality of units derived, actually or conceptually, from molecules of lower relative molecular mass (PAC, 1996, 68, 2291). In a preferred sense according to the present invention a polymer means a compound having >1, preferably ≥5 repeating units, and an oligomer means a compound with >1 and <10, preferably <5, repeating units.

Above and below, in formulae showing a polymer, an oligomer, a compound or a monomeric unit like formula (I), an asterisk (“*”) denotes a linkage to the adjacent repeating unit in the polymer chain or oligomer chain or to a terminal end group.

The terms “repeating unit” and “monomeric unit” mean the constitutional repeating unit (CRU), which is the smallest constitutional unit the repetition of which constitutes a regular macromolecule, a regular oligomer molecule, a regular block or a regular chain (PAC, 1996, 68, 2291).

Unless stated otherwise, the molecular weight is given as the number average molecular weight Mₙ or weight average molecular weight M_{W}, which is determined by gel permeation chromatography (GPC) against polystyrene standards in eluent solvents such as tetrahydrofuran, trichloromethane (TCM, chloroform), chlorobenzene or 1,2,4-trichloro-benzene. Unless stated otherwise, 1,2,4-trichloro-benzene is used as solvent. The degree of polymerization (n) means the number average degree of polymerization given as n=Mₙ/M_{U}, wherein M_{U} is the molecular weight of the single repeating unit as described in J. M. G. Cowie, Polymers: Chemistry & Physics of Modern Materials, Blackie, Glasgow, 1991.

In the polymers according to the the present invention, the total number of repeating units n is preferably ≥5, very preferably ≥10, most preferably ≥20, and preferably up to 2000, very preferably up to 1,000, most preferably up to 100, including any combination of the aforementioned lower and upper limits of n.

The polymers of the present invention include homopolymers, statistical co-polymers, random co-polymers, alternating co-polymers and block co-polymers, and combinations of the aforementioned.

Throughout the description and claims of this specification, the words “comprise” and “contain” and variations of the words, for example “comprising” and “comprises”, mean “including but not limited to”, and are not intended to (and do not) exclude other components.

Aryl and heteroaryl preferably denote a mono-, bi- or tricyclic aromatic or heteroaromatic group having 4 to 30 ring atoms, preferably 5 to 30 ring atoms, particularly preferably 5 to 13 ring atoms that may also comprise condensed rings. Aryl and heteroaryl may be substituted with one or more groups R* as defined or preferably defined below. Heteroaryl means that one or more carbon atoms of the aromatic group are optionally substituted by a heteroatom, which is preferably selected from N, P, As, Si, Ge, O, S, Se and Te.

The substituent R* denotes independently of each other, and on each occurrence identically or differently F, Cl, CN, straight-chain or branched alkyl with 1 to 20 C atoms, straight-chain or branched alkoxy with 1 to 20 C atoms, straight-chain or branched oxaalkyl with 1 to 12 C-atoms, straight-chain or branched thioalkyl with 1 to 12 C atoms, straight-chain or branched fluoroalkyl with 1 to 12 C atoms and straight-chain or branched fluoroalkoxy with 1 to 12 C atoms or straight-chain or branched alkenyl with 2 to 20 C atoms. R* denotes preferably independently of each other, and on each occurrence identically or differently a straight-chain or branched alkyl or alkoxy group with 1 to 16 C atoms. R* denotes particularly preferably independently of each other, and on each occurrence identically or differently a straight-chain or branched alkyl or alkoxy group with 1 to 12 C atoms.

Aryl with 4 to 30 ring atoms denotes an aryl group with 4 to 30 ring atoms and is an aromatic group with aromatic delocalized electrons, optionally substituted one or more times by R*. An aryl group with 6 to 30 C atoms, preferably with 6 to 24 C atoms, is for example 1-, 2-, 3-, 4-, 5- or 6-phenyl, 1-, 2-, 3-, 4-, 6-, 7- or 8-naphthyl, 1-, 2-, 3-, 4-, 6-, 7- or 8-phenanthrenyl, 1-, 2-, 3-, 4-, 5-, 6-, 7-, 8-, 9- or 10-anthracenyl, 1-, 2-, 3-, 4-, 5-, 6-, 7-, 8-, 9-, 10-, 11- or 12-tetracenyl, 1-, 2-, 3-, 4-, 5-, 6-, 7-, 8-, 9-, 10-, 11- or 12-benzo[a]anthracenyl, 1-, 2-, 3-, 4-, 5-, 6-, 7-, 8-, 9-, 10-, 11-, 12-, 13- or 15-pentacenyl, 1-, 2-, 3-, 4-, 5-, 6-, 7-, 8-, 9-, 10-, 11- or 12-chrysenyl, 1-, 2-, 3-, 4-, 5-, 6-, 7-, 8-, 9- or 10-pyrenyl, 1-, 2-, 3-, 4-, 5-, 6-, 7-, 8-, 9-, 10-, 11- or 12-benzo[a]pyrenyl, 1-, 2-, 3-, 4-, 5-, 6-, 7- or 8-azulenyl, 1-, 2-, 3-, 4-, 5-, 6-, 7-, 8-, 9- or 10-fluoranthenyl, 1-, 2-, 3-, 4-, 5-, 6-, 7-, 8-, 9-, 10-, 11- or 12-perylenyl, 1-, 2-, 3-, 4-, 5-, 6- or 7-indenyl or 1-, 2-, 3-, 4-, 5-, 6-, 7-, 8- or 9-fluorenyl which is preferably non-substituted or substituted by R*. Aryl denotes particularly preferably 1-, 2-, 3-, 4-, 5- or 6-phenyl, 1-, 2-, 3-, 4-, 6-, 7- or 8-naphthyl which is non-substituted or substituted by R wherein R* has a meaning as defined above. An arylene with 6 to 30 ring atoms is a bivalent group correspondingly to aryl with 6 to 30 ring atoms.

Heteroaryl preferably denotes a mono- or bicyclic heterocyclic group having 5 to 30 ring members, in which 1, 2 or 3 N and/or 1 or 2 S or O atoms may be present and the heterocyclic radical may be mono- or poly-substituted by R* as described above.

Heteroaryl particularly preferably denotes a mono- or bicyclic heterocyclic group having 5 to 13 ring members, in which 1, 2 or 3 N and/or 1 or 2 S or O atoms may be present and the heterocyclic radical may be mono- or poly-substituted by R* as described above.

The heterocyclic group is particularly preferably substituted or non-substituted 2- or 3-furyl, 2- or 3-thienyl, 1-, 2- or 3-pyrrolyl, 1-, 2-, 4- or 5-imidazolyl, 3-, 4- or 5-pyrazolyl, 2-, 4- or 5-oxazolyl, 3-, 4- or 5-isoxazolyl, 2-, 4- or 5-thiazolyl, 3-, 4- or 5-isothiazolyl, 2-, 3- or 4-pyridyl, 2-, 4-, 5- or 6-pyrimidinyl, furthermore preferably 1,2,3-triazol-1-, -4- or -5-yl, 1,2,4-triazol-1-, -4- or -5-yl, 1- or 5-tetrazolyl, 1,2,3-oxadiazol-4- or -5-yl, 1,2,4-oxadiazol-3- or -5-yl, 1,3,4-thiadiazol-2- or -5-yl, 1,2,4-thiadiazol-3- or -5-yl, 1,2,3-thiadiazol-4- or -5-yl, 2-, 3-, 4-, 5- or 6-2H-thiopyranyl, 2-, 3- or 4-4H-thiopyranyl, 3- or 4-pyridazinyl, pyrazinyl, 2-, 3-, 4-, 5-, 6- or 7-benzofuryl, 2-, 3-, 4-, 5-, 6- or 7-benzothienyl, 1-, 2-, 3-, 4-, 5-, 6- or 7-1H-indolyl, 1-, 2-, 4- or 5-benzimidazolyl, 1-, 3-, 4-, 5-, 6- or 7-benzopyrazolyl, 2-, 4-, 5-, 6- or 7-benzoxazolyl, 3-, 4-, 5-, 6- or 7-benzisoxazolyl, 2-, 4-, 5-, 6- or 7-benzothiazolyl, 2-, 4-, 5-, 6- or 7-benzisothiazolyl, 4-, 5-, 6- or 7-benz-2,1,3-oxadiazolyl, 1-, 2-, 3-, 4-, 5-, 6-, 7- or 8-quinolinyl, 1-, 3-, 4-, 5-, 6-, 7- or 8-isoquinolinyl, 1-, 2-, 3-, 4- or 9-carbazolyl, 1-, 2-, 3-, 4-, 5-, 6-, 7-, 8- or 9-acridinyl, 3-, 4-, 5-, 6-, 7- or 8-cinnolinyl, 2-, 4-, 5-, 6-, 7- or 8-quinazolinyl or 1-, 2- or 3-pyrrolidinyl. A heteroarylene with 5 to 30 ring atoms is a bivalent group correspondingly to heteroaryl with 5 to 30 ring atoms.

A straight-chain or branched alkyl having 1-40 C atoms denotes to the formula CₙH₂ₙ₊₁ in which n is an integer from 1 to 40. Preferably, the alkyl group has 1 to 20 C atoms and corresponds, for example, to methyl, ethyl, iso-propyl, n-propyl, iso-butyl, n-butyl, tert-butyl, n-pentyl, 1-, 2- or 3-methylbutyl, 1,1-, 1,2- or 2,2-dimethylpropyl, 1-ethylpropyl, n-hexyl, n-heptyl, n-octyl, ethylhexyl, n-nonyl, n-decyl, n-undecyl, n-dodecyl, n-tridecyl, n-tetradecyl, n-pentadecyl, n-hexadecyl, n-heptadecyl, n-octadecyl, n-nonadecyl or eicosyl, in which one or more non-adjacent CH₂ groups are optionally replaced by —O—, —S—, —C(O)—, —C(O)—O—, —O—C(O)—, —O—C(O)—O—, —SO₂—, —SO₃—, —NR⁰—, —SiR⁰R⁰⁰—, —CF₂—, —CR⁰═CR⁰⁰—, —CY¹═CY²— or —C≡C— in such a manner that O and/or S atoms are not linked directly to one another, and in which one or more H atoms are optionally replaced by F, Cl, Br, I or CN. The replacement with one or more F atoms comprises the perfluorination of the corresponding group.

Cyclic alkyl groups having 1 to 40 C atoms are preferably cycloalkyl groups having 3-7 C atoms such as cyclopropyl, cyclobutyl, cyclopentyl, cyclohexyl or cycloheptyl, in which one or more non-adjacent CH₂ groups are optionally replaced by —O—, —S—, —C(O)—, —C(O)—O—, —O—C(O)—, —O—C(O)—O—, —SO₂—, —SO₃—, —NR—, —Si R⁰R⁰⁰—, —CF₂—, —CR⁰═CR⁰⁰—, —CY¹═CY²— or —C≡C— in such a manner that O and/or S atoms are not linked directly to one another, and in which one or more H atoms are optionally replaced by F, Cl, Br, I or CN.

A straight-chain or branched alkenyl having 2 to 20 C atoms, in which a plurality of double bonds may also be present, is, for example, allyl, 2- or 3-butenyl, iso-butenyl, sec-butenyl, furthermore 4-pentenyl, iso-pentenyl, hexenyl, heptenyl, octenyl, —C₉H₁₇, —C₁₀H₁₉ to —C₂₀H₃₉, preferably allyl, 2- or 3-butenyl, iso-butenyl, sec-butenyl, furthermore preferably 4-pentenyl, iso-pentenyl or hexenyl, which may be optionally partially fluorinated.

Especially preferred alkenyl groups are C₂-C₇-1E-alkenyl, C₄-C₇-3E-alkenyl, C₅-C₇-4-alkenyl, C₆-C₇-5-alkenyl and C₇-6-alkenyl, in particular C₂-C₇-1E-alkenyl, C₄-C₇-3E-alkenyl and C₅-C₇-4-alkenyl. Examples for particularly preferred alkenyl groups are vinyl, 1E-propenyl, 1E-butenyl, 1E-pentenyl, 1E-hexenyl, 1E-heptenyl, 3-butenyl, 3E-pentenyl, 3E-hexenyl, 3E-heptenyl, 4-pentenyl, 4Z-hexenyl, 4E-hexenyl, 4Z-heptenyl, 5-hexenyl, 6-heptenyl and the like. Groups having up to 5 C atoms are generally preferred.

A straight-chain or branched alkynyl having 2 to 20 C atoms, in which a plurality of triple bonds may also be present, is, for example, ethynyl, 1- or 2-propynyl, 2- or 3-butynyl, furthermore 4-pentynyl, 3-pentynyl, hexynyl, hept-ynyl, octynyl, —C₉H₁₅, —C₁₀H₁₇ to —C₂₀H₃₇, preferably ethynyl, 1- or 2-propyn-yl, 2- or 3-butynyl, 4-pentynyl, 3-pentynyl or hexynyl, which may be optionally partially fluorinated.

An alkyl group where one CH₂ group is replaced by —O—, is preferably straight-chain 2-oxapropyl (=methoxymethyl), 2-(=ethoxymethyl) or 3-oxabutyl (=2-methoxyethyl), 2-, 3-, or 4-oxapentyl, 2-, 3-, 4-, or 5-oxahexyl, 2-, 3-, 4-, 5-, or 6-oxaheptyl, 2-, 3-, 4-, 5-, 6- or 7-oxaoctyl, 2-, 3-, 4-, 5-, 6-, 7- or 8-oxanonyl or 2-, 3-, 4-, 5-, 6-, 7-, 8- or 9-oxadecyl, for example. Oxaalkyl, i.e. where one CH₂ group is replaced by —O—, is preferably straight-chain 2-oxapropyl (=methoxymethyl), 2-(=ethoxymethyl) or 3-oxabutyl (=2-methoxyethyl), 2-, 3-, or 4-oxapentyl, 2-, 3-, 4-, or 5-oxahexyl, 2-, 3-, 4-, 5-, or 6-oxaheptyl, 2-, 3-, 4-, 5-, 6- or 7-oxaoctyl, 2-, 3-, 4-, 5-, 6-, 7- or 8-oxanonyl or 2-, 3-, 4-, 5-, 6-, 7-, 8- or 9-oxadecyl, for example.

In an alkyl group wherein one CH₂ group is replaced by —O— and one by —CO—, these radicals are preferably neighboured. Accordingly these radicals together form a carbonyloxy group —CO—O— or an oxycarbonyl group —O—CO—. Preferably this group is straight-chain and has 2 to 6 C atoms. It is accordingly preferably acetyloxy, propionyloxy, butyryloxy, pentanoyloxy, hexanoyloxy, acetyloxymethyl, propionyloxymethyl, butyryloxymethyl, pentanoyloxymethyl, 2-acetyloxyethyl, 2-propionyloxyethyl, 2-butyryloxyethyl, 3-acetyloxypropyl, 3-propionyloxypropyl, 4-acetyloxybutyl, methoxycarbonyl, ethoxycarbonyl, propoxycarbonyl, butoxycarbonyl, pentoxycarbonyl, methoxycarbonylmethyl, ethoxy-carbonylmethyl, propoxycarbonylmethyl, butoxycarbonylmethyl, 2-(methoxycarbonyl)ethyl, 2-(ethoxycarbonyl)ethyl, 2-(propoxy-carbonyl)ethyl, 3-(methoxycarbonyl)propyl, 3-(ethoxycarbonyl)propyl, 4-(methoxycarbonyl)-butyl.

An alkyl group wherein two or more CH₂ groups are replaced by —O— and/or —COO— can be straight-chain or branched. It is preferably straight-chain and has 3 to 12 C atoms. Accordingly it is preferably bis-carboxy-methyl, 2,2-bis-carboxy-ethyl, 3,3-bis-carboxy-propyl, 4,4-bis-carboxy-butyl, 5,5-bis-carboxy-pentyl, 6,6-bis-carboxy-hexyl, 7,7-bis-carboxy-heptyl, 8,8-bis-carboxy-octyl, 9,9-bis-carboxy-nonyl, 10,10-bis-carboxy-decyl, bis-(methoxycarbonyl)-methyl, 2,2-bis-(methoxycarbonyl)-ethyl, 3,3-bis-(methoxycarbonyl)-propyl, 4,4-bis-(methoxycarbonyl)-butyl, 5,5-bis-(methoxycarbonyl)-pentyl, 6,6-bis-(methoxycarbonyl)-hexyl, 7,7-bis-(methoxycarbonyl)-heptyl, 8,8-bis-(methoxycarbonyl)-octyl, bis-(ethoxycarbonyl)-methyl, 2,2-bis-(ethoxycarbonyl)-ethyl, 3,3-bis-(ethoxycarbonyl)-propyl, 4,4-bis-(ethoxycarbonyl)-butyl, 5,5-bis-(ethoxycarbonyl)-hexyl.

A thioalkyl group, i.e where one CH₂ group is replaced by —S—, is preferably straight-chain thiomethyl (—SCH₃), 1-thioethyl (—SCH₂CH₃), 1-thiopropyl (=—SCH₂CH₂CH₃), 1-(thiobutyl), 1-(thiopentyl), 1-(thiohexyl), 1-(thioheptyl), 1-(thiooctyl), 1-(thiononyl), 1-(thiodecyl), 1-(thioundecyl) or 1-(thiododecyl), wherein preferably the CH₂ group adjacent to the sp² hybridised vinyl carbon atom is replaced.

A fluoroalkyl group is preferably straight-chain perfluoroalkyl CₜF₂ₜ₊₁, wherein t is an integer from 1 to 15, in particular CF₃, C₂F₅, C₃F₇, C₄F₉, C₅F₁₁, C₆F₁₃, C₇F₁₅ or C₈F₁₇, very preferably C₆F₁₃.

The above-mentioned alkyl, alkoxy, alkenyl, oxaalkyl, thioalkyl, carbonyl and carbonyloxy groups can be achiral or chiral groups. Particularly preferred chiral groups are 2-butyl (=1-methylpropyl), 2-methylbutyl, 2-methylpentyl, 3-methylpentyl, 2-ethylhexyl, 2-propylpentyl, in particular 2-methylbutyl, 2-methylbutoxy, 2-methylpentoxy, 3-methylpentoxy, 2-ethyl-hexoxy, 1-methylhexoxy, 2-octyloxy, 2-oxa-3-methylbutyl, 3-oxa-4-methyl-pentyl, 4-methylhexyl, 2-hexyl, 2-octyl, 2-nonyl, 2-decyl, 2-dodecyl, 6-meth-oxyoctoxy, 6-methyloctoxy, 6-methyloctanoyloxy, 5-methylheptyloxy-carbonyl, 2-methylbutyryloxy, 3-methylvaleroyloxy, 4-methylhexanoyloxy, 2-chloropropionyloxy, 2-chloro-3-methylbutyryloxy, 2-chloro-4-methyl-valeryl-oxy, 2-chloro-3-methylvaleryloxy, 2-methyl-3-oxapentyl, 2-methyl-3-oxahexyl, 1-methoxypropyl-2-oxy, 1-ethoxypropyl-2-oxy, 1-propoxypropyl-2-oxy, 1-butoxypropyl-2-oxy, 2-fluorooctyloxy, 2-fluorodecyloxy, 1,1,1-trifluoro-2-octyloxy, 1,1,1-trifluoro-2-octyl, 2-fluoromethyloctyloxy for example. Very preferred are 2-hexyl, 2-octyl, 2-octyloxy, 1,1,1-trifluoro-2-hexyl, 1,1,1-trifluoro-2-octyl and 1,1,1-trifluoro-2-octyloxy.

Preferred achiral branched groups are isopropyl, isobutyl (=methylpropyl), isopentyl (=3-methylbutyl), tert. butyl, isopropoxy, 2-methyl-propoxy and 3-methylbutoxy.

The substituents R⁰ and R⁰⁰ and R⁰⁰⁰ are independently of each other and denote alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —Si(R*)₂—, —N(R*)₂—, —CHR*═CR*— or —C≡C— such that O- and/or S-atoms are not directly linked to each other; aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups; or denote H wherein R* has one of the meanings as described above.

The substituents R⁰, R⁰⁰ and R⁰⁰⁰ are preferably independently of each other H or a straight-chain or branched alkyl or alkoxyl group having 1 to 12 C atoms. The substituents R⁰, R⁰⁰ and R⁰⁰⁰ are particularly preferably independently of each other H, methyl, ethyl, n-propyl, isopropyl, n-butyl, n-octyl, 2-ethylhexyl, n-dodecyl, methoxy or ethoxy.

Y¹ and Y² independently of each other denote F, Cl or CN wherein one of Y¹ or Y² may additionally denote H; preferably each independently F or CN wherein one of Y¹ or Y² may additionally denote H.

—CY¹═CY²— is preferably —CF═CF— or —CH═C(CN)—.

—CR⁰═CR⁰⁰— is preferably —CH═CH—. —SiR⁰R⁰⁰— is preferably —Si(CH₃)₂—, —Si(CH₂CH₃)₂—, —Si(OCH₃)₂—, —Si(OCH₂CH₃)₂— and Si(OCH(CH₃)₂)₂—.

In a preferred embodiment of the invention, L¹, L², L³ and L⁴ within the monomeric unit of formula (I) denote independently of each other, and on each occurrence identically or differently —C(═O)—, —C(═O)—O—, —O—C(═O)—, —CF₂— or a terminal group —F or —CN, in which case the respective e, f, g, h are defined as 0.

In a particularly preferred embodiment of the invention, L¹, L², L³ and L⁴ within the monomeric unit of formula (I) denote —C(═O)—O— or —O—C(═O)—.

The invention therefore relates to a device as described or preferably described before wherein the polymer, oligomer or compound comprising at least one monomeric unit according to formula (I) is contained in which L¹ to L⁴ denote independently of each other, and on each occurrence identically or differently —C(═O)—, —C(═O)—O—, —O—C(═O)—, —CF₂— or a terminal group —F or —CN, in which case the respective e, f, g, h are defined as 0.

In a preferred embodiment of the invention, R¹ and R² within the monomeric unit of formula (I) denote independently of each other H, halogen, straight-chain, branched or cyclic alkyl with 1 to 20 C atoms, aryl or heteroaryl having 4 to 30 ring atoms which are optionally substituted one or more times by R*. In a particularly preferred embodiment of the invention, R¹ and R² within the monomeric unit of formula (I) denote independently of each other a straight-chain alkyl group with 1 to 16 C atoms. In a very particularly preferred embodiment of the invention, R¹ and R² within the monomeric unit of formula (I) denote independently of each other a straight-chain alkyl group with 6, 7, 8, 10, 12, 14 or 16 carbon atoms and accordingly is preferably hexyl, heptyl, octyl, decyl, dodecyl, tetradecyl or hexadecyl, or a branched-chain alkyl group with 6 to 20 carbon atoms and accordingly is preferably 1-methylpentyl, 1-methylheptyl, 2-ethylhexyl, 2-butylhexyl, 2-ethyloctyl, 2-butyloctly, 2-hexyloctyl, 2-ethyldecyl, 2-butyldecyl, 2-hexyldecyl, 2-octyldecyl, 2-ethyldodecyl, 2-butyldodecyl, 2-hexyldodecyl, 2-octyldodecyl, 2-decyldodecyl, 3-ethylheptyl, 3-butylheptyl, 3-ethylnonyl, 3-butylnonyl, 3-hexylnonyl, 3-ethylundecyl, 3-butylundecyl, 3-hexylundecyl, 3-octylundecyl, 4-ethyloctyl, 4-butyloctyl, 4-ethyldecyl, 4-butyldecyl, 4-hexyldecyl, 4-ethyldodecyl, 4-butyldodecyl, 4-hexyldodecyl, 4-octyldodecyl.

The invention therefore relates to a device as described or preferably described before wherein the polymer, oligomer or compound comprising at least one monomeric unit according to formula (I) is contained in which R¹ and R² independently of each other denote H, halogen, straight-chain, branched or cyclic alkyl with 1 to 20 C atoms, aryl or heteroaryl having 4 to 30 ring atoms which are optionally substituted one or more times by R*.

In a preferred embodiment of the invention, R³ and R⁴ denote H.

The invention therefore relates to a device as described or preferably described before wherein the polymer, oligomer or compound comprising at least one monomeric unit according to formula (I) is contained in which R³ and R⁴ are H.

In a preferred embodiment of the invention, a, b, e, f, g and h are 1 and c and d are 0 wherein R¹ to R⁴ and L¹ to L⁴ has a meaning as described or preferably described above.

The invention therefore relates to a device as described or preferably described before wherein the polymer, oligomer or compound comprising at least one monomeric unit according to formula (I) is contained in which a, b, e, f, g and h are 1 and c and d are 0.

In another preferred embodiment of the invention, b, c, d, e, f, g and h are 1 and a and b are 0 wherein R¹ to R⁴ and L¹ to L⁴ has a meaning as described or preferably described above.

Especially preferred monomeric units according to formula (I) corresponds to formulae (Ia), (Ib), (Ic), (Id), (Ie), (If), (Ih), (Ii) and (Ij),

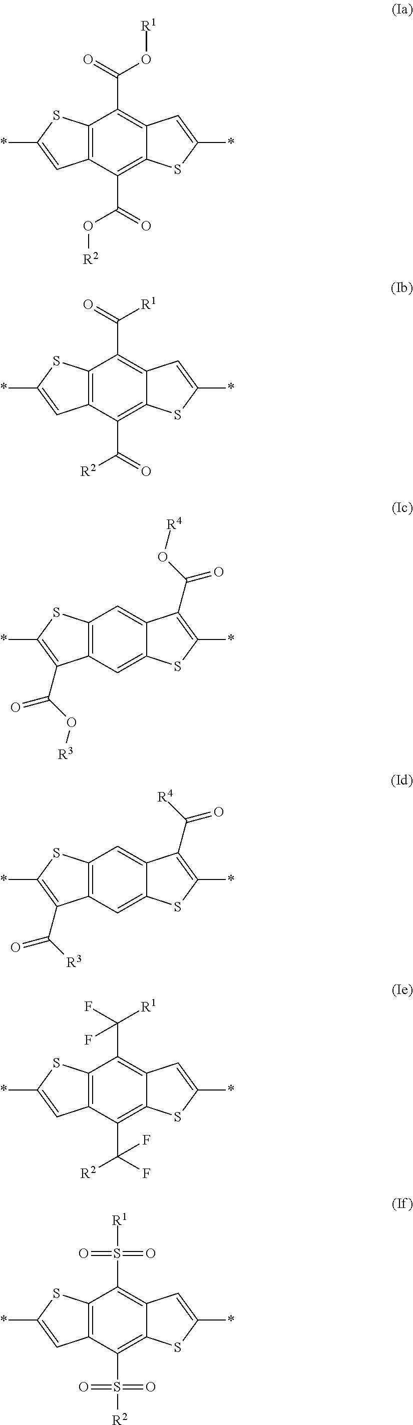

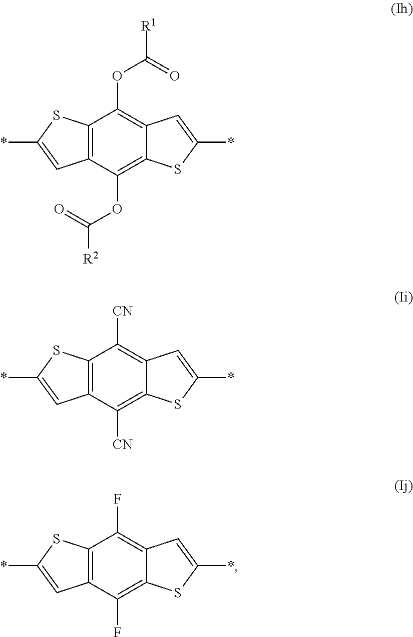

wherein
R¹⁻⁴ independently of each other denote H, halogen, straight-chain, branched or cyclic alkyl with 1 to 40 C atoms, in which one or more non-adjacent CH₂ groups are optionally replaced by —O—, —S—, —C(O)—, —C(O)—O—, —O—C(O)—, —O—C(O)—O—, —SO₂—, —SO₃—, —NR⁰—, —SiR⁰R⁰⁰—, —CF₂—, —CR⁰═CR⁰⁰—, —CY¹═CY²— or —C≡C— in such a manner that O and/or S atoms are not linked directly to one another, and in which one or more H atoms are optionally replaced by F, Cl, Br, I or CN, or aryl or heteroaryl having 4 to 30 ring atoms which are optionally substituted;
Y¹ and Y² independently of each other denote F, Cl or CN wherein one of Y¹ or Y² may additionally denote H;
R⁰⁻⁰⁰ independently of each other denote alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —Si(R*)₂—, —N(R*)₂—, —CR*═CR*— or —C≡C— such that O- and/or S-atoms are not directly linked to each other;
   aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
   or denote H;
R* independently of each other, and on each occurrence identically or differently denotes F, Cl, CN, straight-chain or branched alkyl with 1 to 20 C atoms, straight-chain or branched alkoxy with 1 to 20 C atoms, straight-chain or branched oxaalkyl with 1 to 12 C-atoms, straight-chain or branched thioalkyl with 1 to 12 C atoms, straight-chain or branched fluoroalkyl with 1 to 12 C atoms and straight-chain or branched fluoroalkoxy with 1 to 12 C atoms or straight-chain or branched alkenyl with 2 to 20 C atoms;
   or wherein R¹, R², R³ and R⁴ have a preferred meaning as described above.

Particularly especially preferred monomeric units according to formula (I) corresponds to formulae (la) and (Ih), wherein R¹, R², R³ and R⁴ have a meaning or a preferred meaning as described above.

Especially preferred are oligomers or compounds of formula (II)

R^{t1}-(A¹)ᵢ-(A²)ⱼ-[(A³)ₖ-(A⁴)ₗ-U-(A⁵)ₘ-(A⁶)ₒ]_{n′}-(A⁷)ₚ-(A⁸)_{q}-R^{t2} (II),

wherein
U corresponds to formula (I) as described and preferably described before,
A¹⁻⁸ independently of each other denote —CY^{1′}═CY^{2′}—, —C≡C—, arylene having 6 to 30 ring atoms which may be substituted by one or more groups R or heteroarylene having 5 to 30 ring atoms which may be substituted by one or more groups R, and one or more of A¹⁻⁸ may also denote U,
Y^{1′}, Y^{2′} independently of each other denote H, F, Cl or CN,
R is alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —SiR⁰R⁰⁰—, —NR⁰R⁰⁰—, —CR⁰═CR⁰⁰— or —C≡C— such that O- and/or S-atoms are not directly linked to each other;
   aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
   or denote H,
R^{t1, t2} independently of each other denote H, F, Cl, Br, —CN, —CF₃, R, —CF₂—R⁰, —O—R⁰, —S—R⁰, —SO₂—R⁰, —SO³—R⁰, —C(═O)—R⁰, —C(═S)—R⁰, —C(═O)—CF₂—R⁰, —C(═O)—OR⁰, —C(═S)—OR⁰, —O—C(═O)—R⁰, —O—C(═S)—R⁰, —C(═O)—SR⁰, —S—C(═O)—R⁰, —C(═O)NR⁰R⁰⁰, —NR⁰—C(═O)—R⁰⁰, —NHR⁰, —NR⁰R⁰⁰, —CR⁰═CR⁰⁰R⁰⁰⁰, —C≡C—R⁰, —C≡C—SiR⁰R⁰⁰R⁰⁰⁰, —SiR⁰R⁰⁰R⁰⁰⁰, —CH═C(CN)—C(O)—OR⁰, —CH═C(COOR⁰)(COOR⁰⁰), —CH═C(CONR⁰R⁰⁰)₂, —CH═C(CN)(Ar⁹),

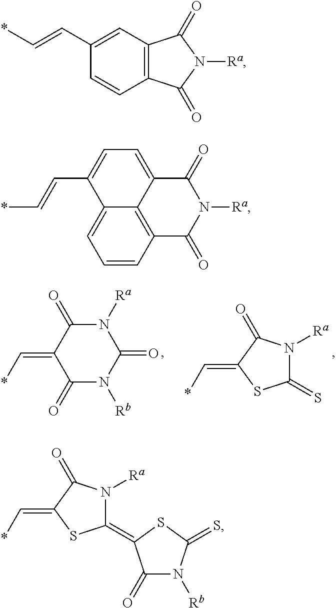

R⁰, R⁰⁰, R⁰⁰⁰ independently of each other denote
   alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —Si(R*)₂—, —N(R*)₂—, —CR*═CR*— or —C≡C— such that O- and/or S-atoms are not directly linked to each other;
   aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
   or denote H,
R^{a}, R^{b} are independently of each other aryl or heteroaryl, each having from 4 to 30 ring atoms and being unsubstituted or substituted with one or more groups R,
R* independently of each other, and on each occurrence identically or differently denotes F, Cl, CN, straight-chain or branched alkyl with 1 to 20 C atoms, straight-chain or branched alkoxy with 1 to 20 C atoms, straight-chain or branched oxaalkyl with 1 to 12 C-atoms, straight-chain or branched thioalkyl with 1 to 12 C atoms, straight-chain or branched fluoroalkyl with 1 to 12 C atoms and straight-chain or branched fluoroalkoxy with 1 to 12 C atoms or straight-chain or branched alkenyl with 2 to 20 C atoms;
Ar⁹ is aryl or heteroaryl, each having from 5 to 30 ring atoms and being unsubstituted or substituted with one or more groups R,
i, j, k, l, m, o, p, q are independently of each other 0 or 1, with at least one of i, j, k, l, m, o, p or q being 1,
n′ is 1, 2 or 3.

The invention therefore relates to a device as described or preferably described before wherein the oligomer or compound comprising at least one monomeric unit according to formula (I) corresponds to formula (II) as described before wherein R^{t1}, A¹ to A⁸, R^{t2}, i, j, k, l, m, o, p and q have the meanings as described before or especially described below.

Ar⁹ is an aryl or heteroaryl group which has electron donor properties or electron acceptor properties having 5 to 30 ring atoms which may be substituted by one or more groups R or heteroarylene having 5 to 30 ring atoms which may be substituted by one or more groups R. Preferably, Ar⁹ denotes aryl and heteroaryl groups selected from the group D1 to D147 and A1 to A101 as described below.

Especially preferred polymers contain or consist of one or more repeating units of formulae (III) to (IX) and the repeating units build regioregular, alternated, regiorandom, statistical, block or random homopolymer or co-polymer backbones,

*—(U)ᵤ—* (III)

*—(U)ᵤ-(A⁹)ₓ-* (IV)

*-(A⁹)ₓ-(U)ᵤ-(A¹⁰)_{y}-(A¹¹)_{z}-(A¹²)ₛ-* (V)

*—(U)ᵤ-(A⁹)ₓ-(A¹⁰)_{y}-(A¹¹)_{z}-(A¹²)ₛ-* (VI)

*-(A⁹)ₓ-(A¹⁰)_{y}-(U)ᵤ-(A¹¹)_{z}-(A¹²)ₛ-* (VII)

*—(U)ᵤ-(A⁹)ₓ-(A¹⁰)_{y}-(U)ᵥ-(A¹¹)_{z}-(A¹²)ₛ-* (VIII)

*—(U)ᵤ-(A⁹)ₓ-(U)ᵥ-(A¹⁰)_{y}-(U)_{w}-(A¹¹)_{z}-* (IX),

wherein
U corresponds to formula (I) as described and preferably described before,
A⁹⁻¹² independently of each other denote —CY^{1′}═CY^{2′}—, —C≡C—, arylene having 6 to 30 ring atoms which may be substituted by one or more groups R or heteroarylene having 5 to 30 ring atoms which may be substituted by one or more groups R,
Y^{1′}, Y^{2′} independently of each other denote H, F, Cl or CN,
R is alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —SiR⁰R⁰⁰—, —NR⁰R⁰⁰—, —CR⁰═CR⁰⁰— or —C≡C— such that O- and/or S-atoms are not directly linked to each other;
   aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
   or denote H,
R⁰, R⁰⁰ independently of each other denote
   alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —Si(R*)₂—, —N(R*)₂—, —CR*═CR*— or —C≡C— such that O- and/or S-atoms are not directly linked to each other;
   aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
   or denote H,
R* independently of each other, and on each occurrence identically or differently denotes F, Cl, CN, straight-chain or branched alkyl with 1 to 20 C atoms, straight-chain or branched alkoxy with 1 to 20 C atoms, straight-chain or branched oxaalkyl with 1 to 12 C-atoms, straight-chain or branched thioalkyl with 1 to 12 C atoms, straight-chain or branched fluoroalkyl with 1 to 12 C atoms and straight-chain or branched fluoroalkoxy with 1 to 12 C atoms or straight-chain or branched alkenyl with 2 to 20 C atoms;
u, v, w are independently of each other an integer ≥1,
x, y, z, s are independently of each other and denote 0 or an integer ≥1, with at least one of x, y, z or s being ≥1.

The invention therefore relates to a device as described or preferably described before wherein the polymer comprising at least one monomeric unit according to formula (I) contains or alternatively consists of one or more of the repeating units corresponding to formulae (III) to (IX) and the repeating units build regioregular, alternated, regiorandom, statistical, block or random homopolymer or co-polymer backbones as described before, wherein U, u, A⁹ to A¹², x, y, z and s have the meanings as described before or especially described below.

In the above formulae (II), (III), (IV), (V), (VI), (VII), (VIII), (IX) and (X), A¹ to A⁸ and A⁹ to A¹² are preferably defined as an electron accepting or an electron donatying arylene or heteroarylene unit selected from the electron donating units (D1) to (D147) and the electron accepting units (A1) to (A101),

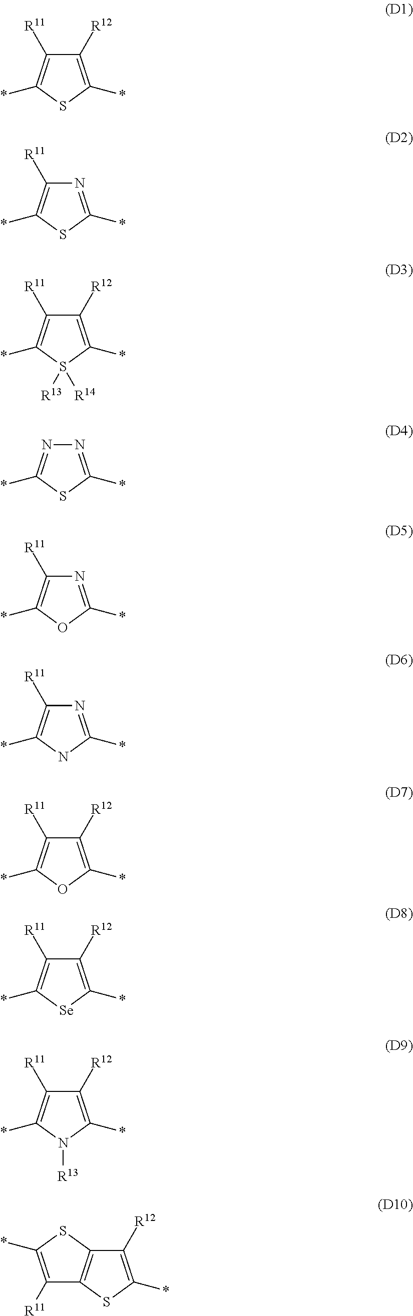

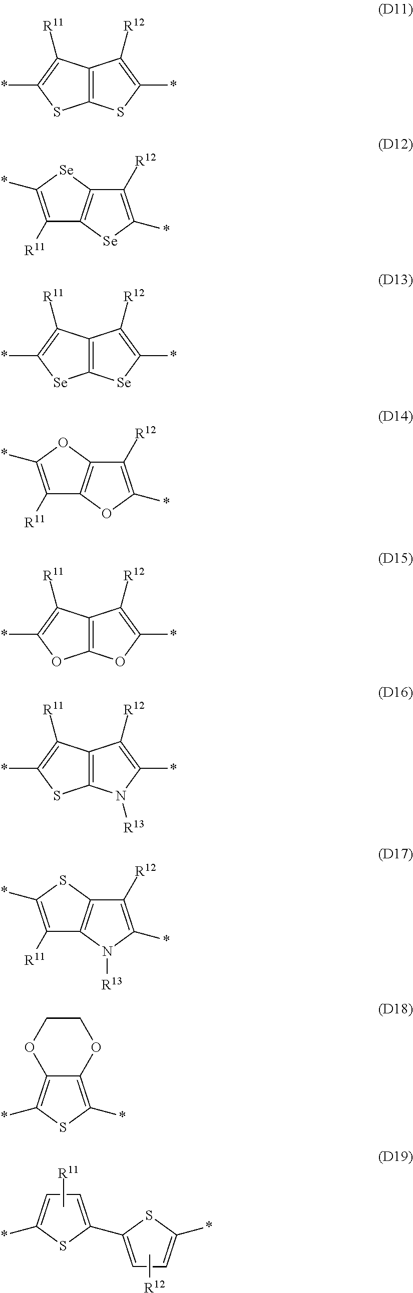

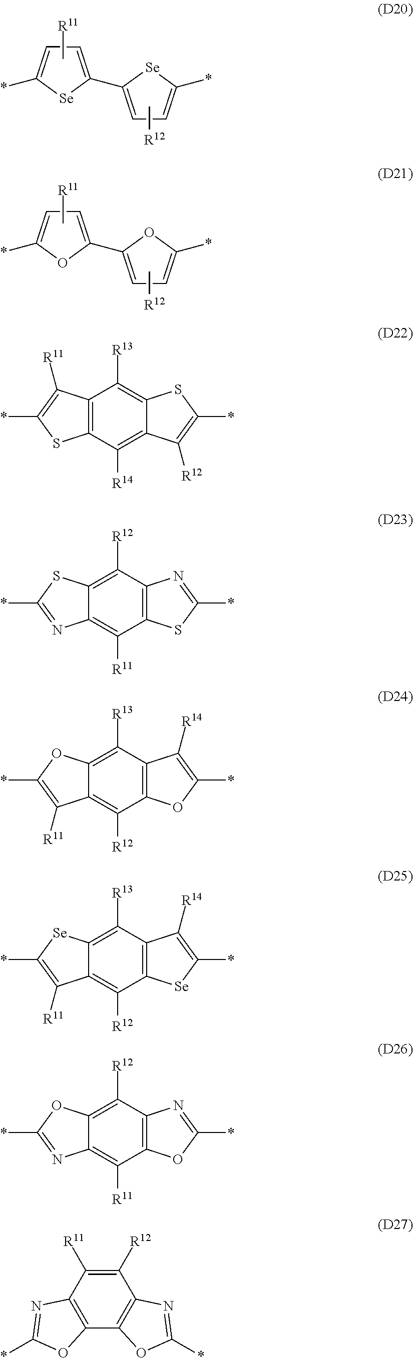

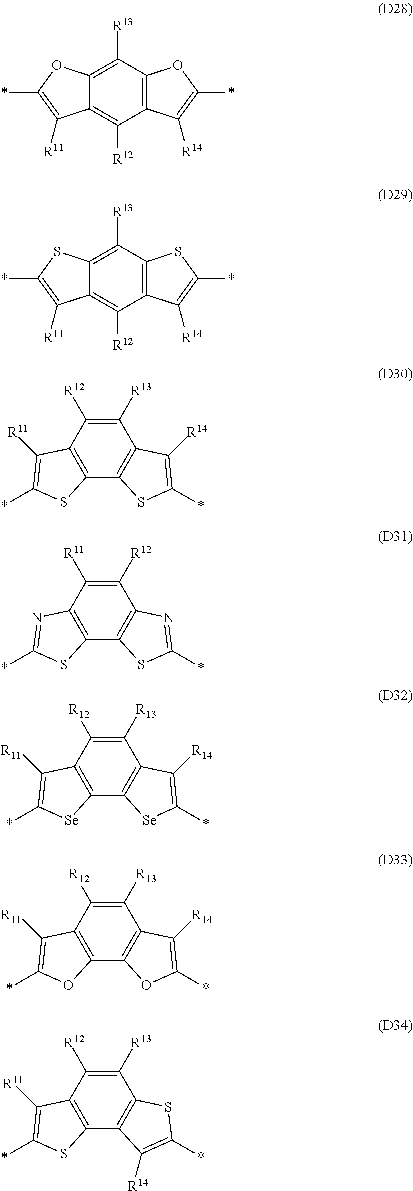

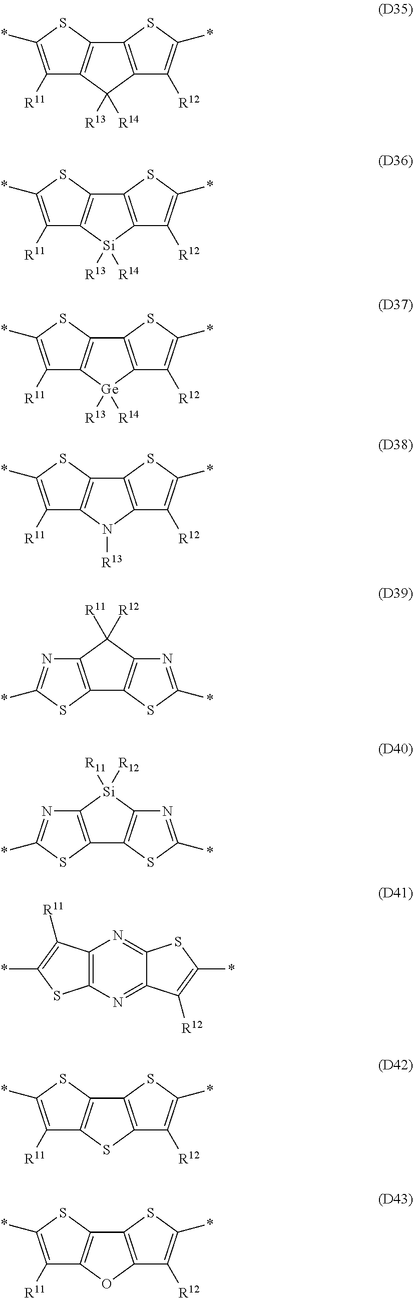

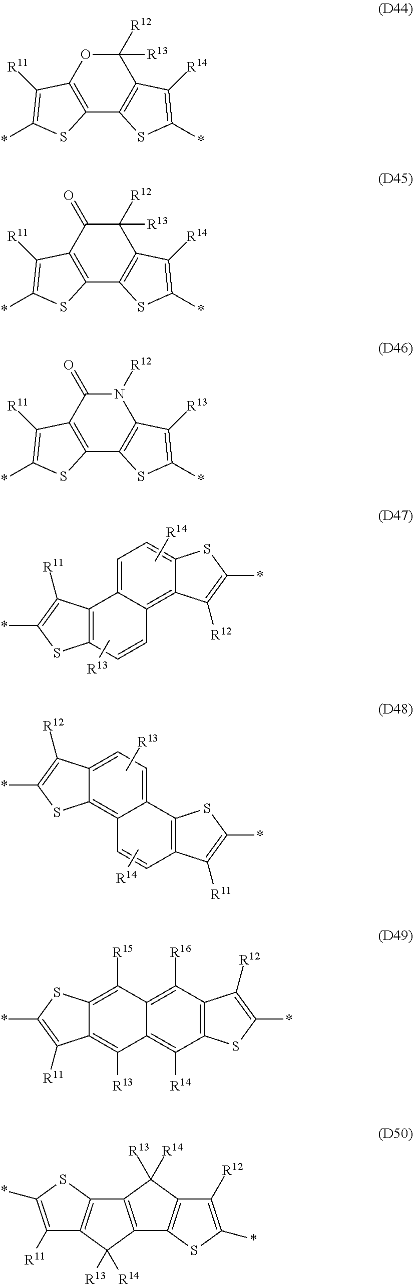

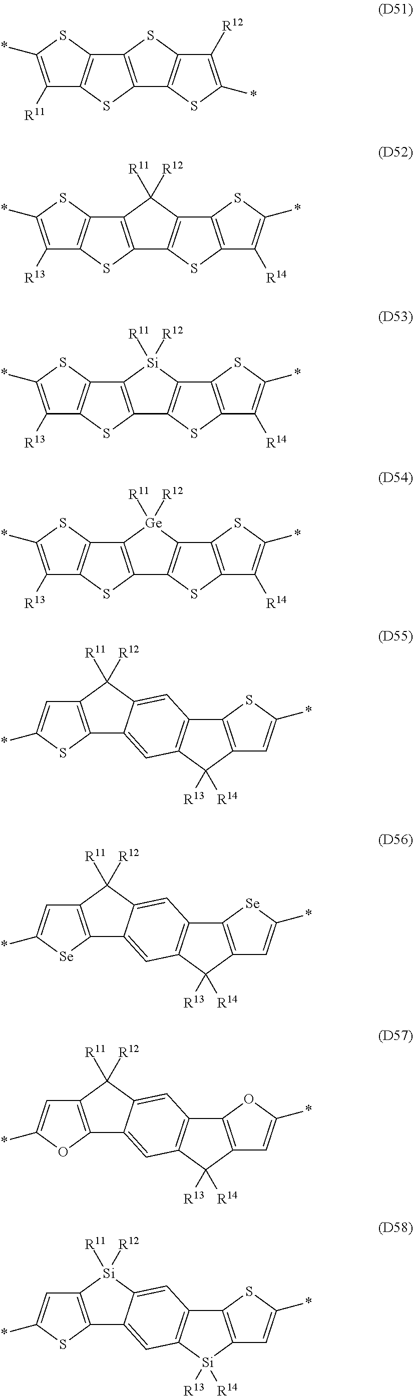

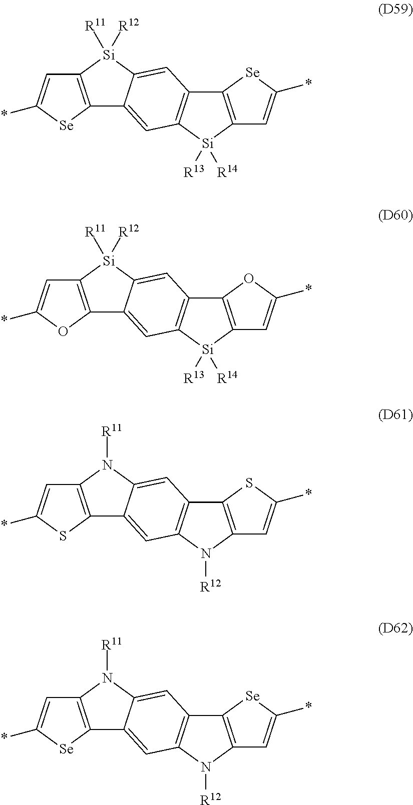

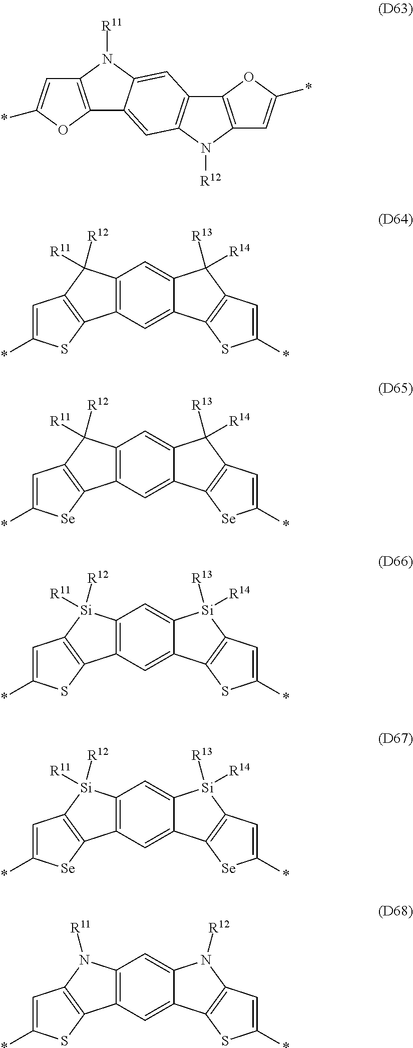

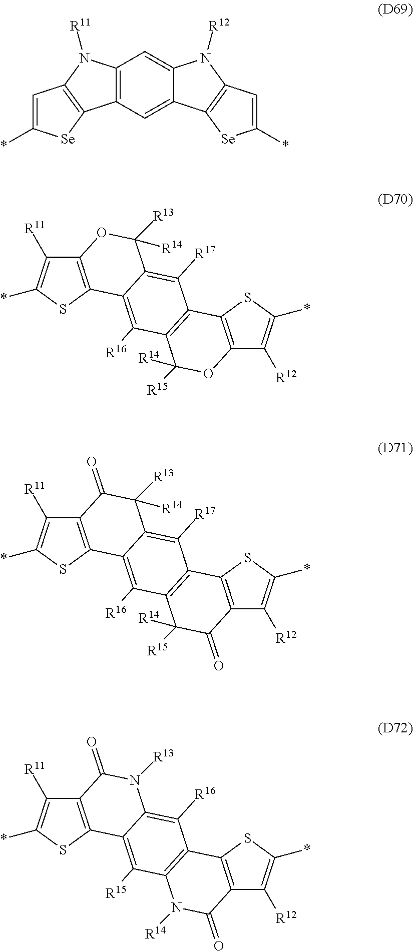

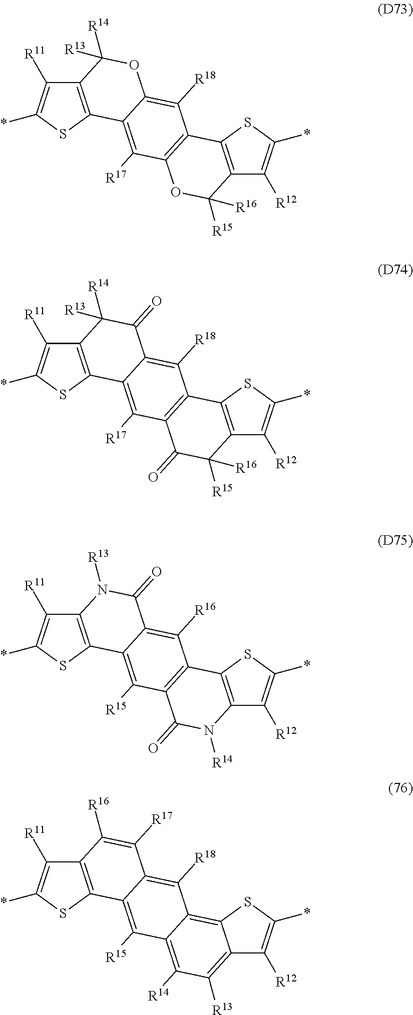

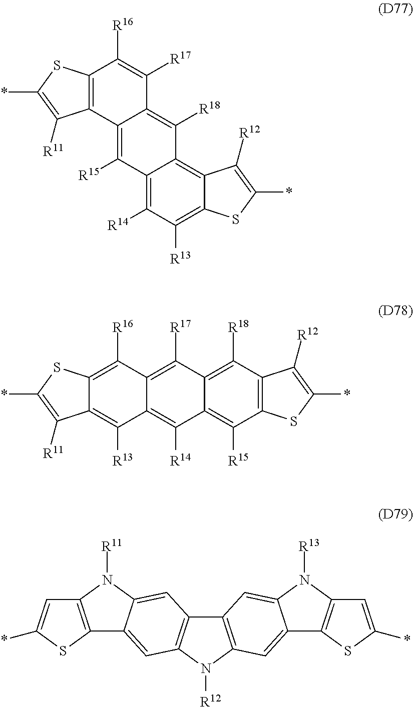

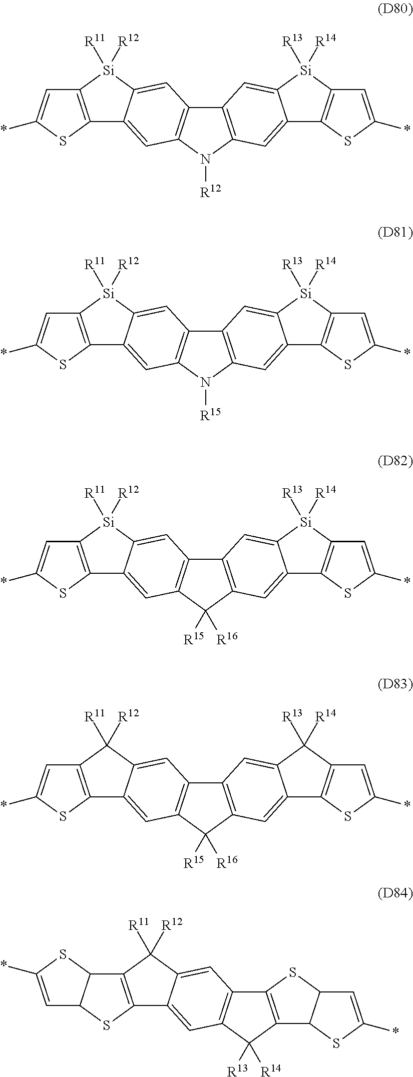

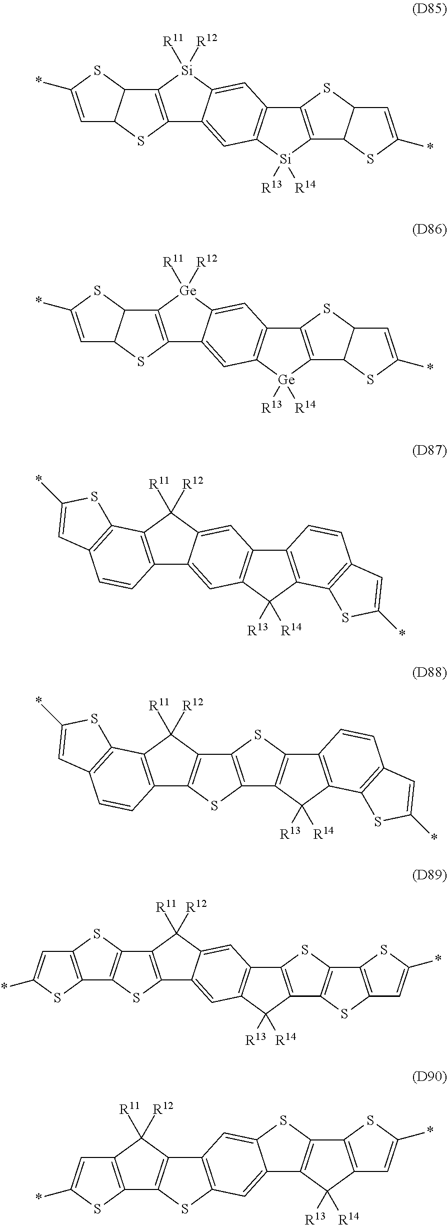

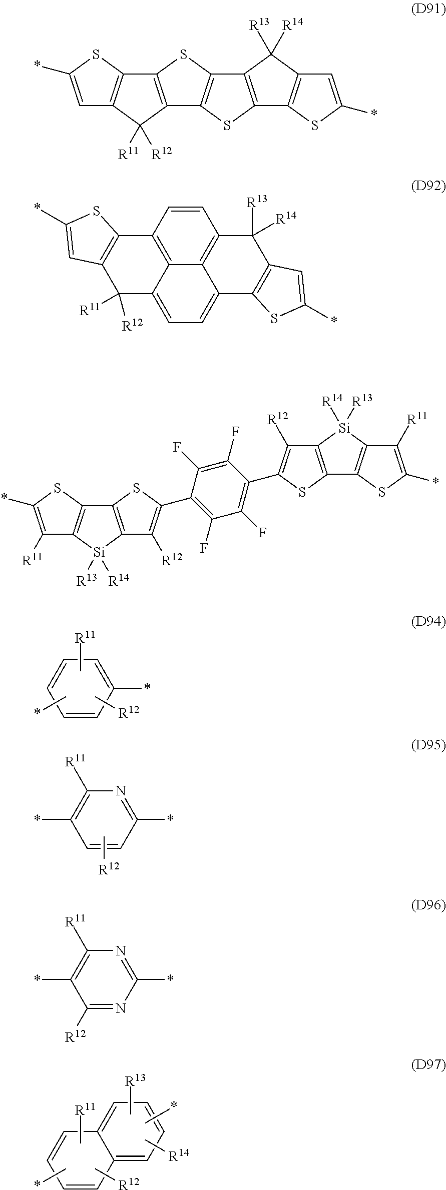

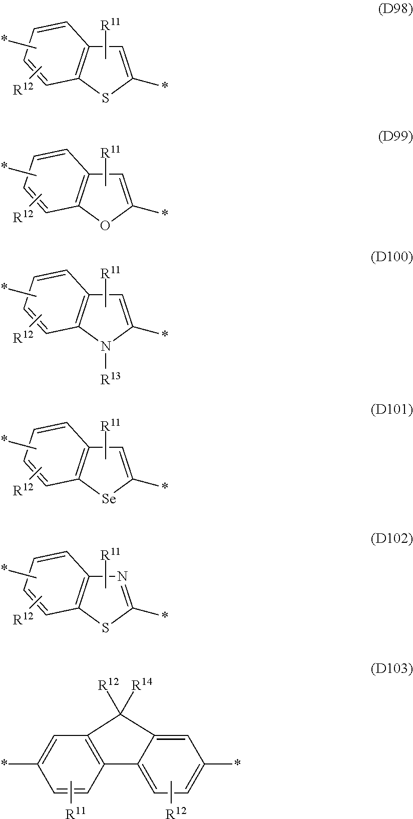

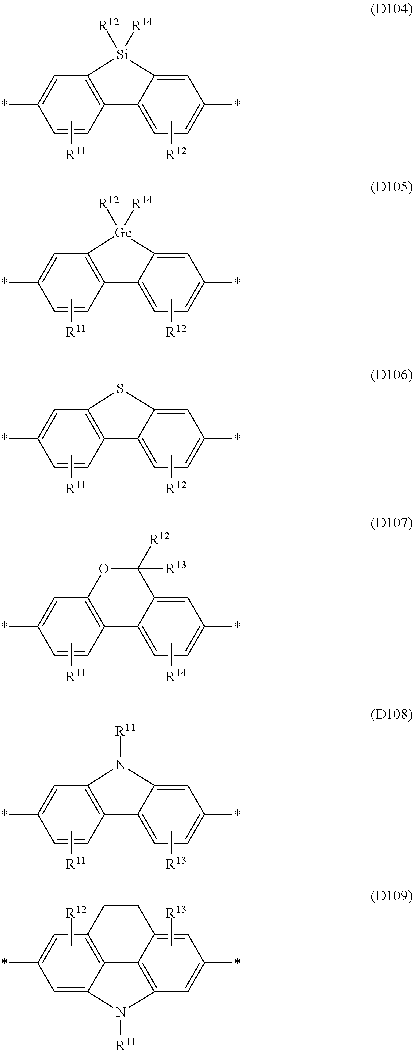

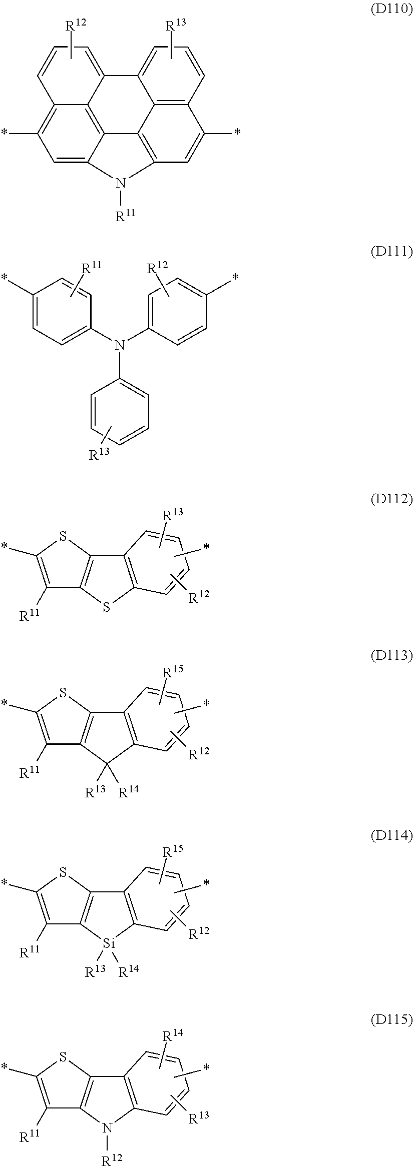

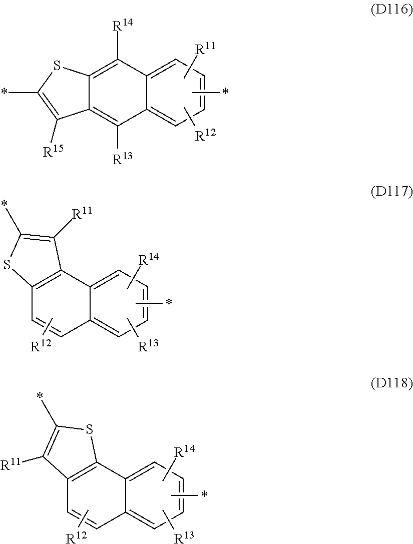

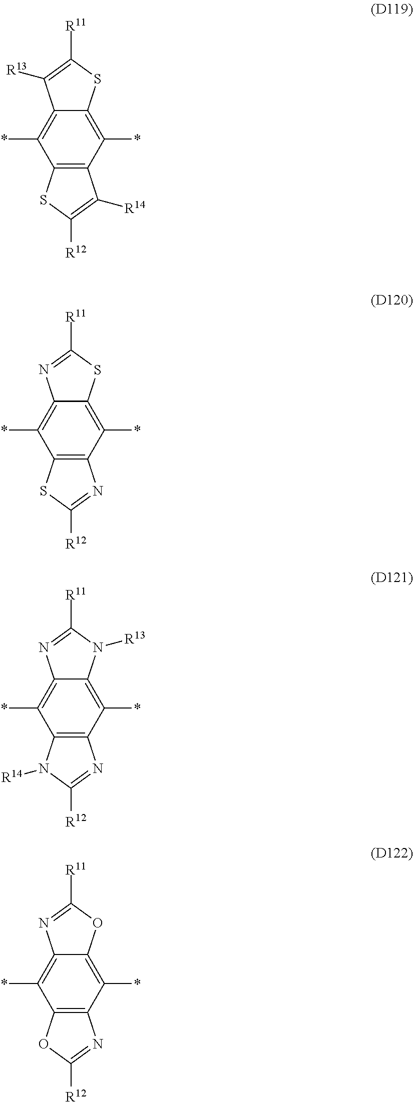

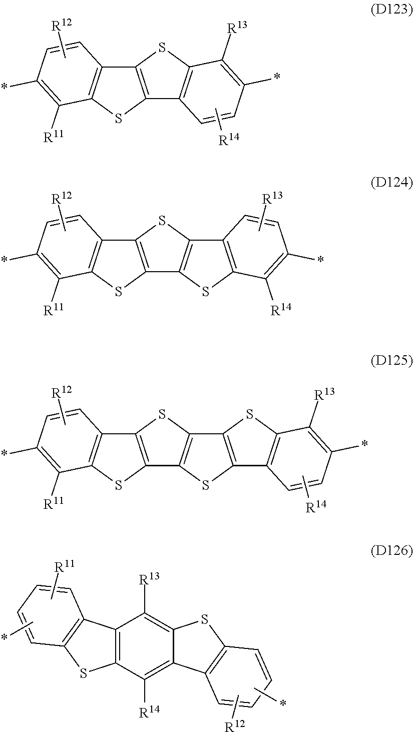

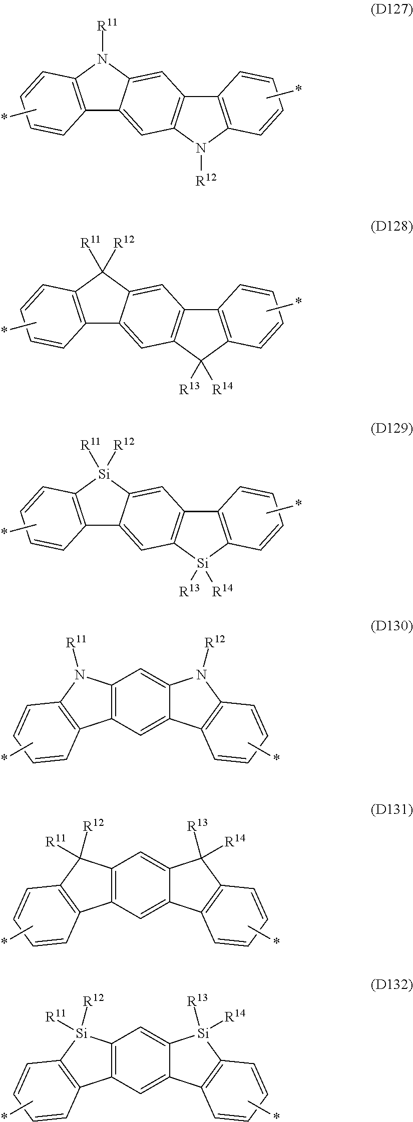

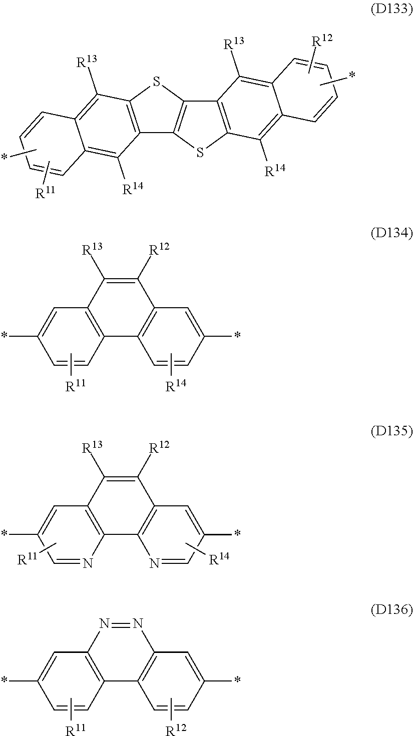

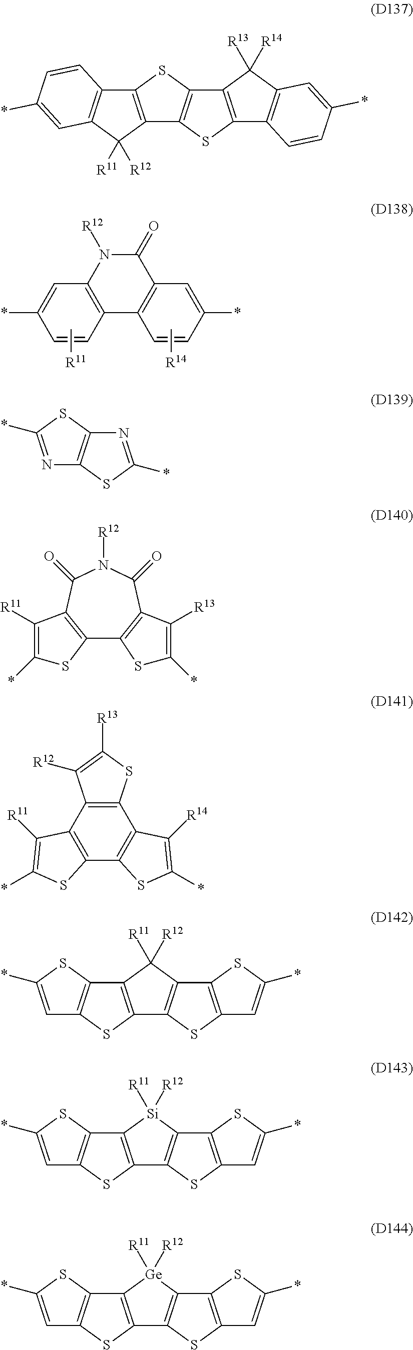

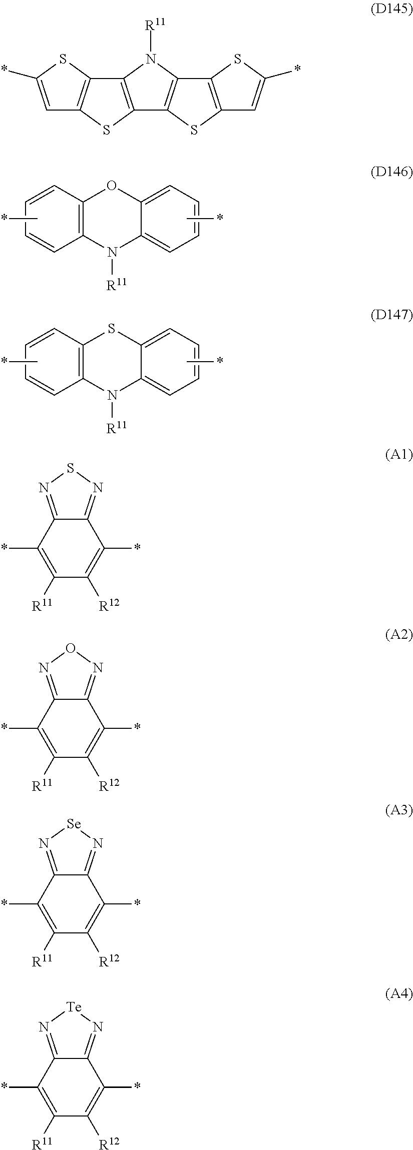

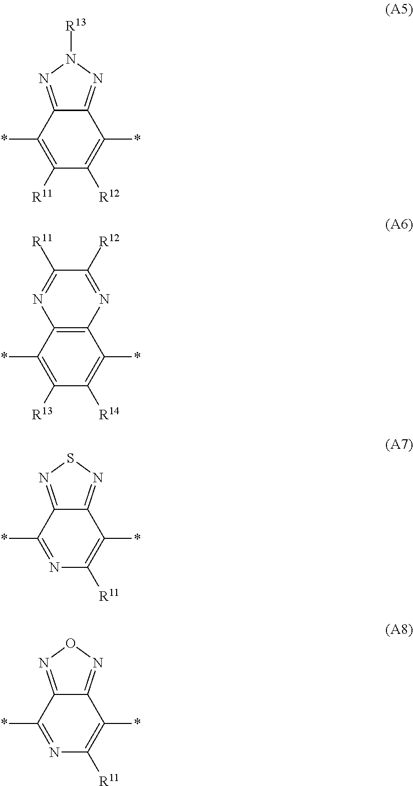

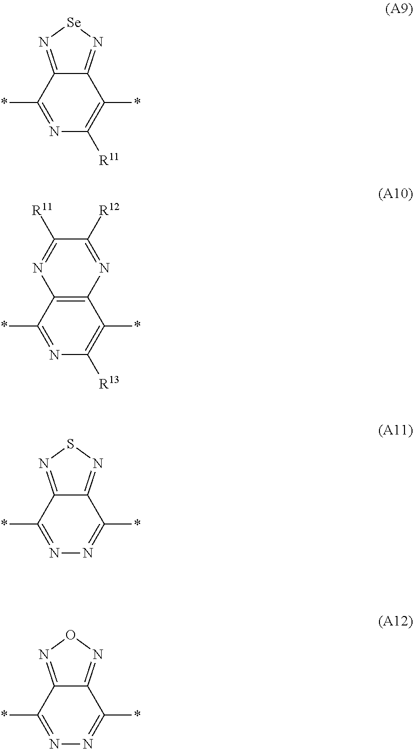

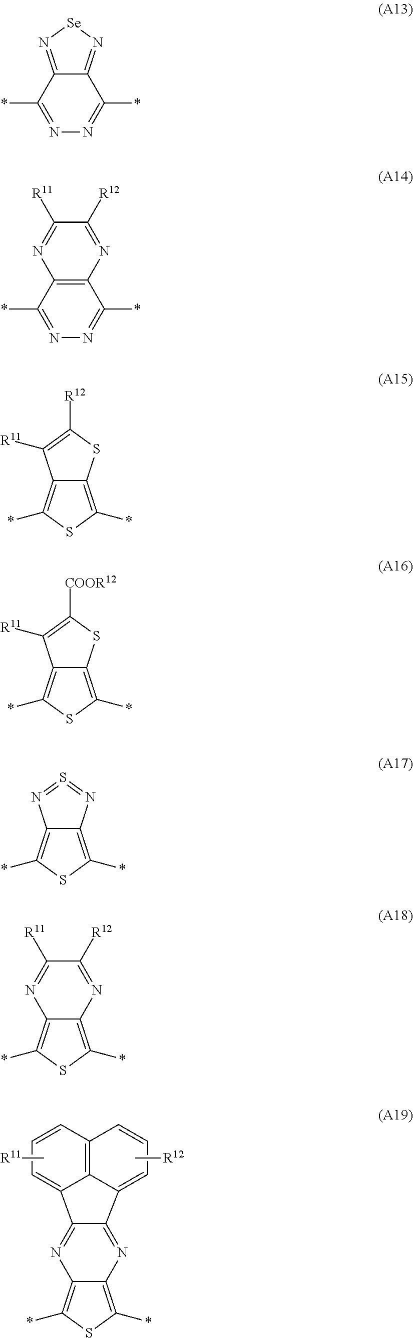

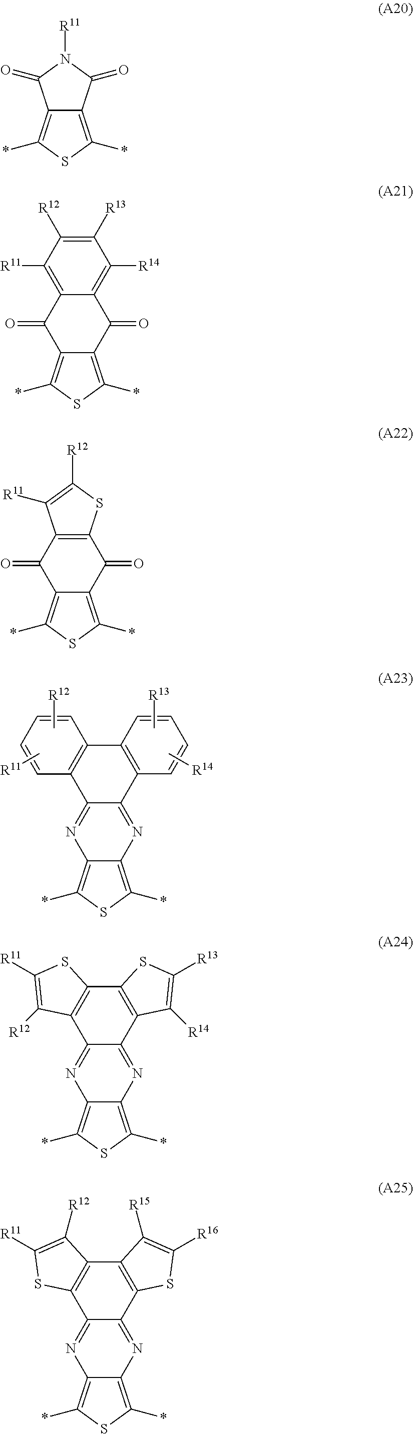

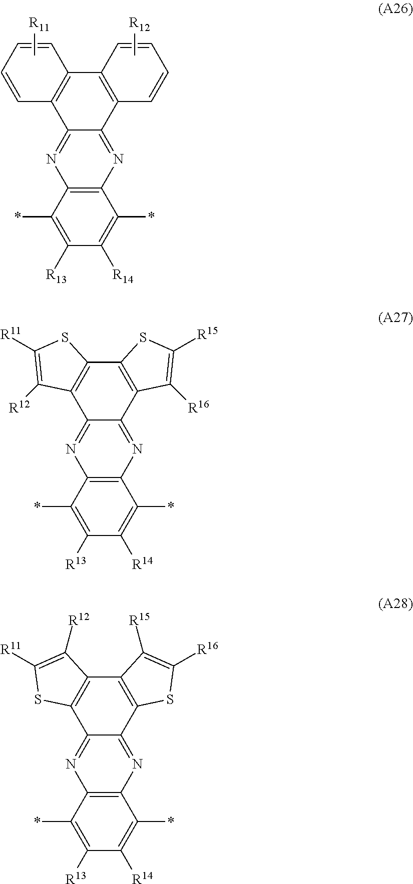

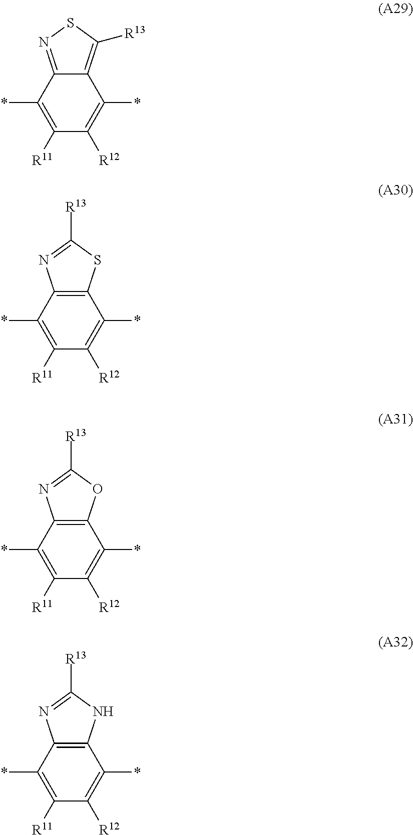

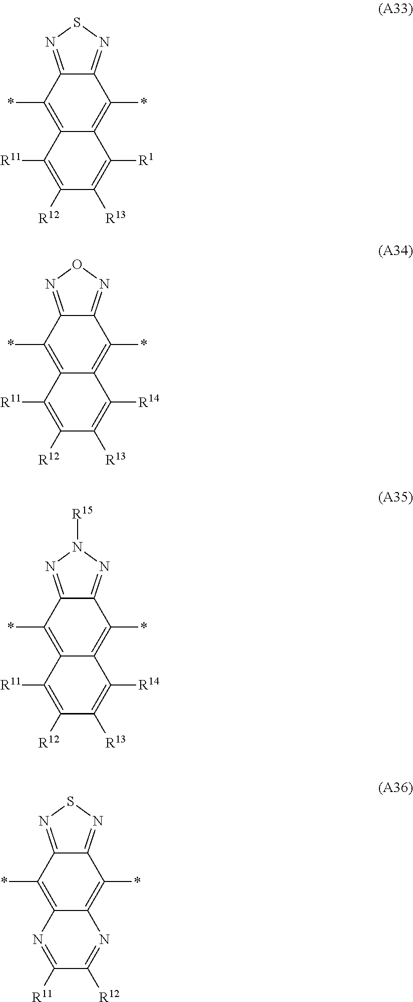

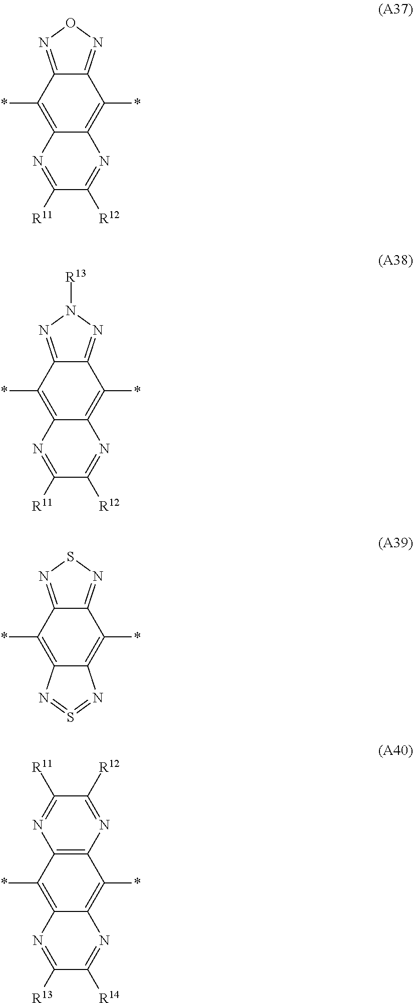

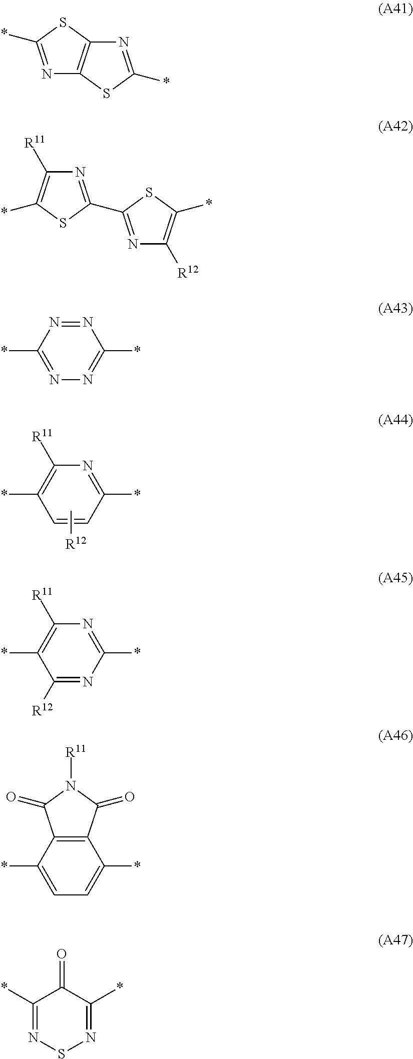

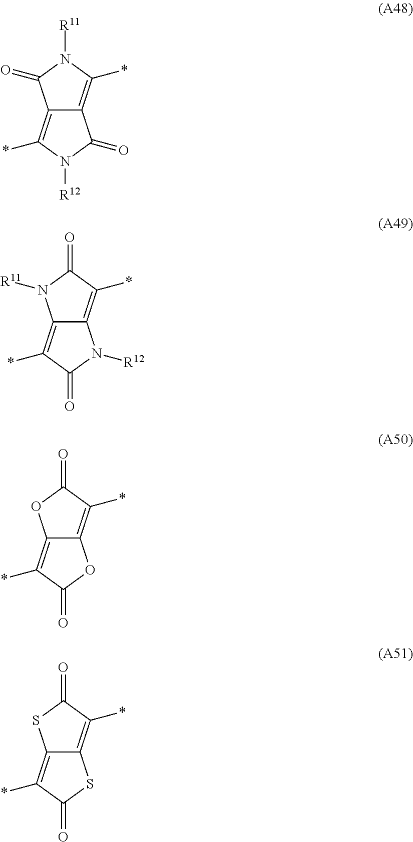

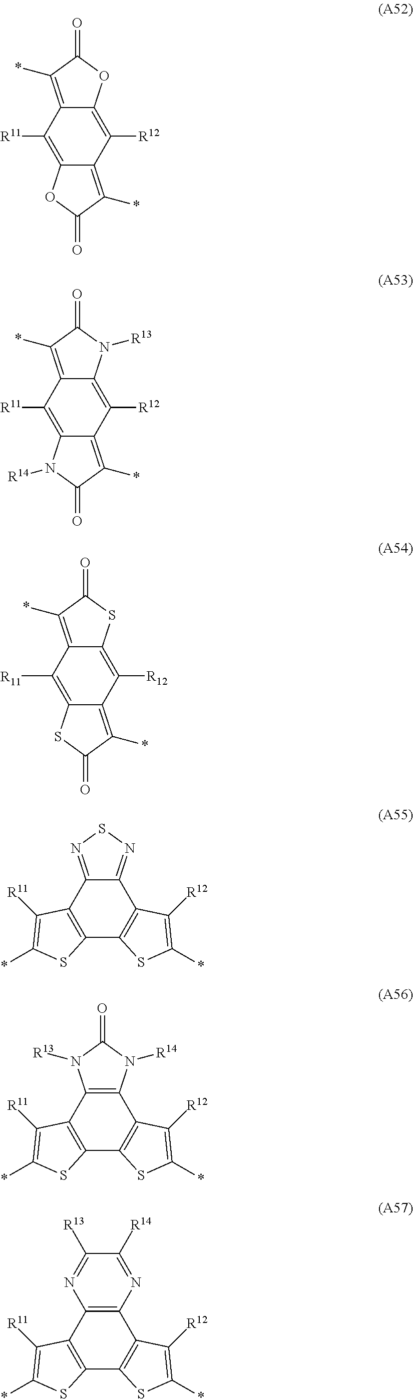

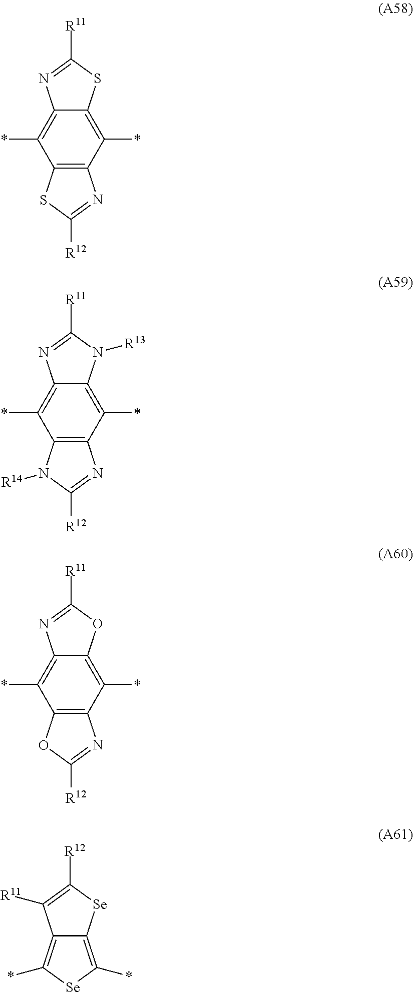

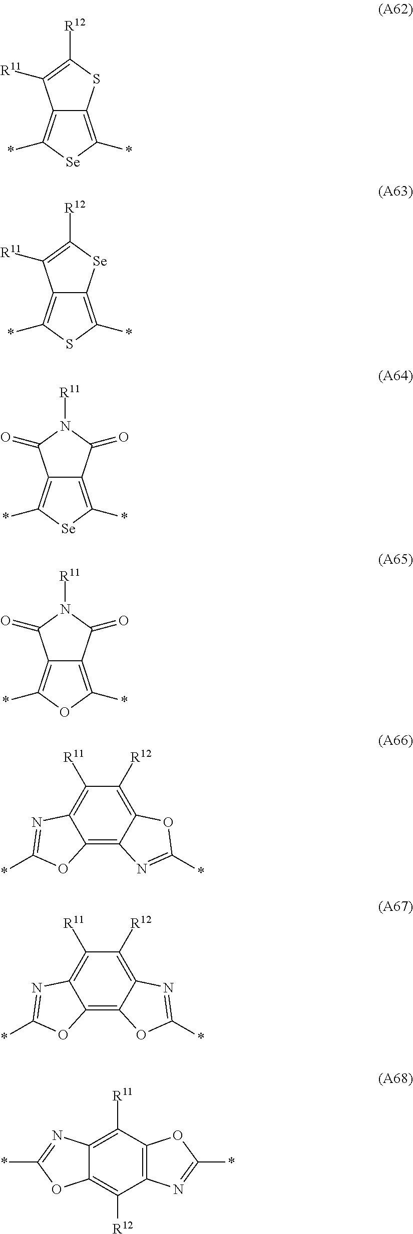

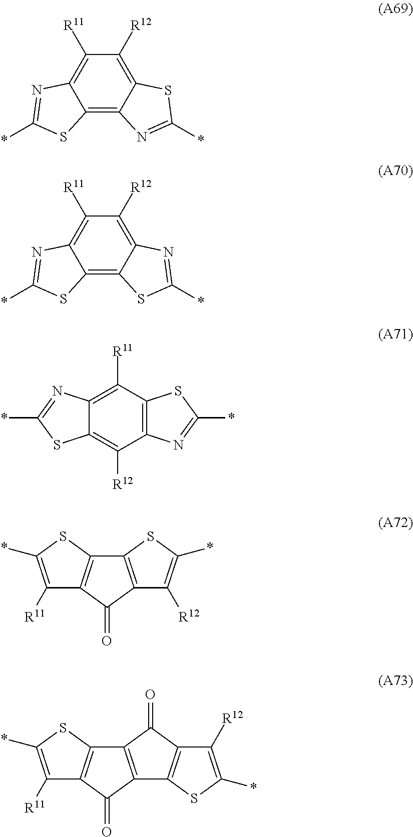

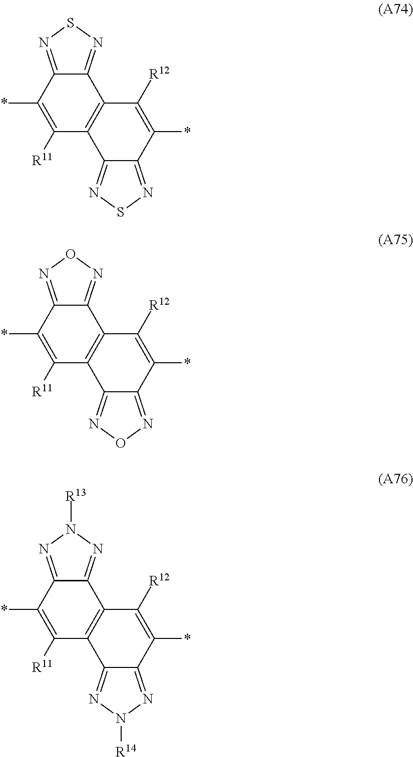

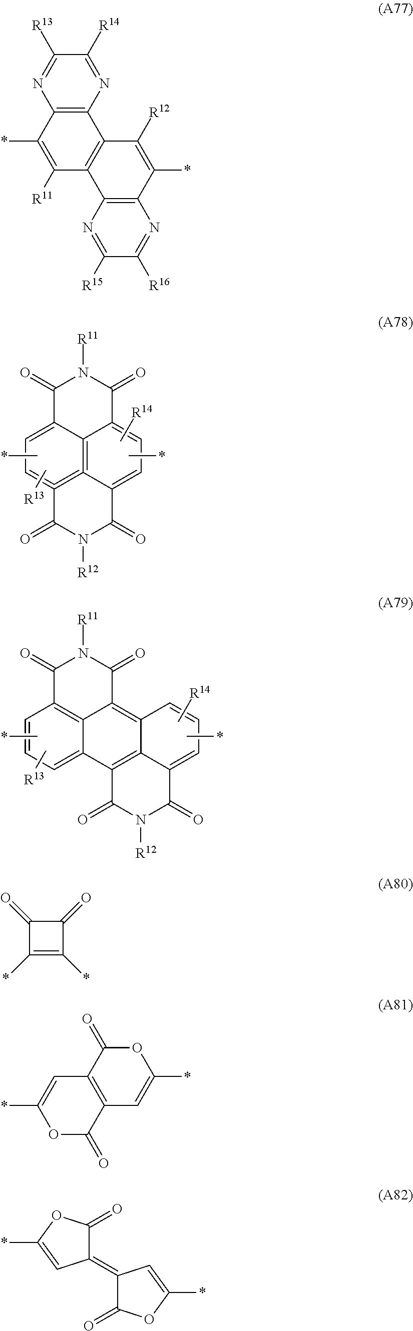

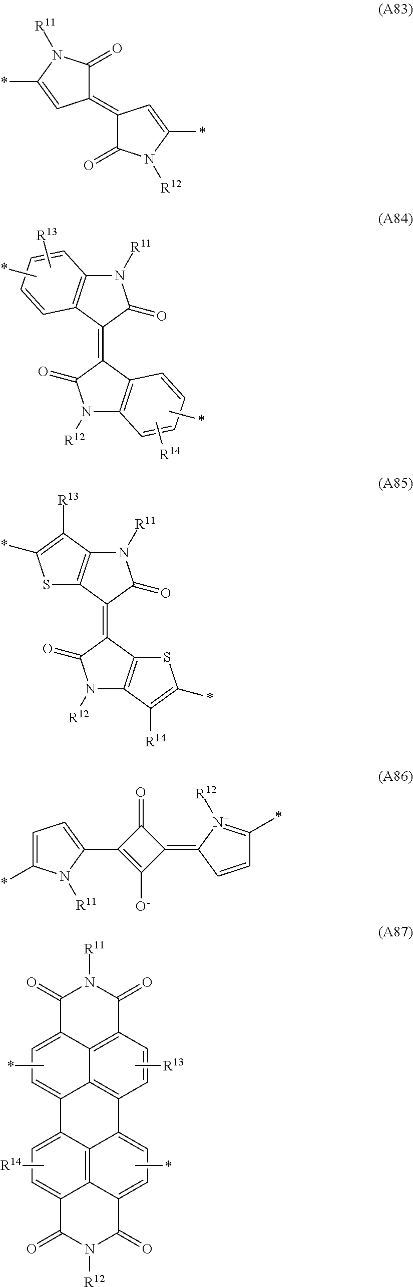

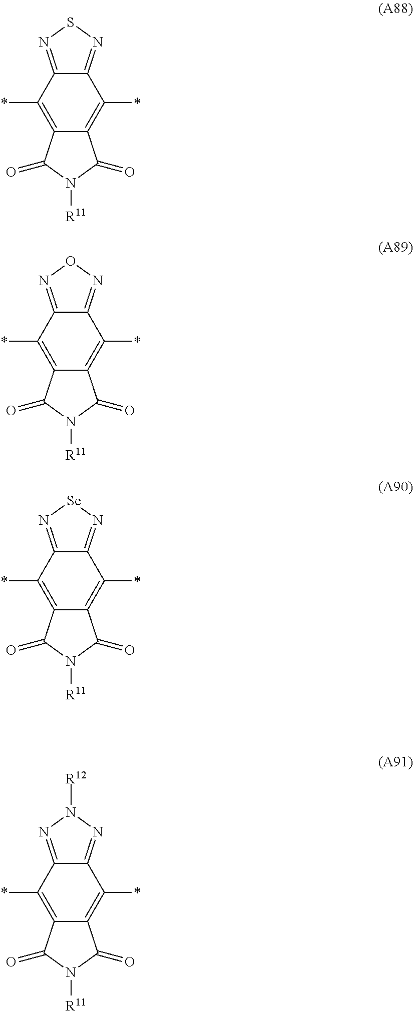

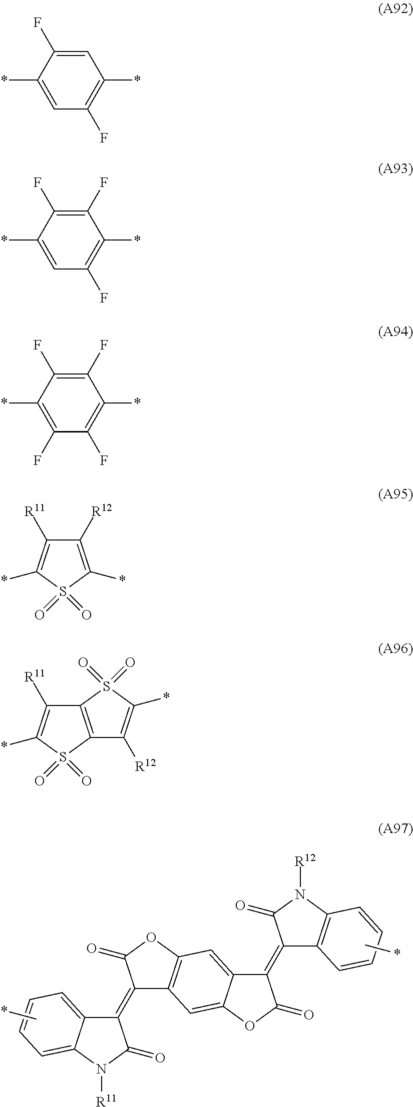

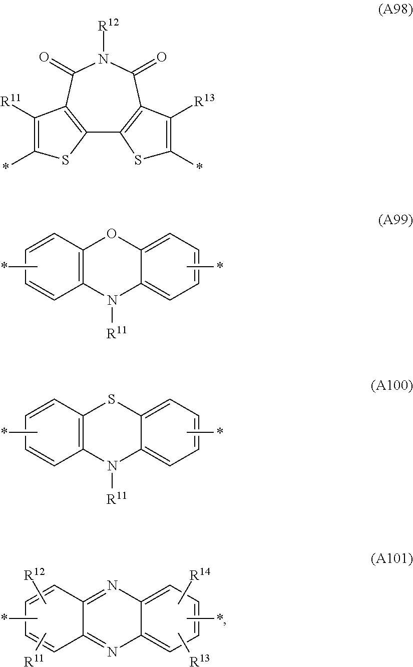

wherein
R¹¹⁻¹⁸ independently of each each other have one of the meanings of R, aryl or heteroaryl, each having from 4 to 30 ring atoms and being unsubstituted or substituted with one or more groups R or denote H, F, Cl, Br, —CN, —CF₃ or NO₂ and
R is alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —SiR⁰R⁰⁰—, —NR⁰R—, —CR⁰═CR⁰⁰— or —C≡C— such that O- and/or S-atoms are not directly linked to each other;
   aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
   or denote H,
R⁰, R⁰⁰ independently of each other denote alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —Si(R*)₂—, —N(R*)₂—, —CR*═CR*— or —C≡C— such that O- and/or S-atoms are not directly linked to each other;
   aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
   or denote H and
R* independently of each other, and on each occurrence identically or differently denotes F, Cl, CN, straight-chain or branched alkyl with 1 to 20 C atoms, straight-chain or branched alkoxy with 1 to 20 C atoms, straight-chain or branched oxaalkyl with 1 to 12 C-atoms, straight-chain or branched thioalkyl with 1 to 12 C atoms, straight-chain or branched fluoroalkyl with 1 to 12 C atoms and straight-chain or branched fluoroalkoxy with 1 to 12 C atoms or straight-chain or branched alkenyl with 2 to 20 C atoms.

In the above repeating units of formulae (II), (III), (IV), (V), (VI), (VII), (VIII) and (IX), A¹ to A⁸ and A⁹ to A¹² are particularly preferably (D1), (A1) and/or (A18), wherein R¹¹ to R¹⁸ has one of the meanings as described or preferably described below.

Preferred small molecules and oligomers according to formula (II) correspond to formulae (IIa), (IIb) or (IIc),

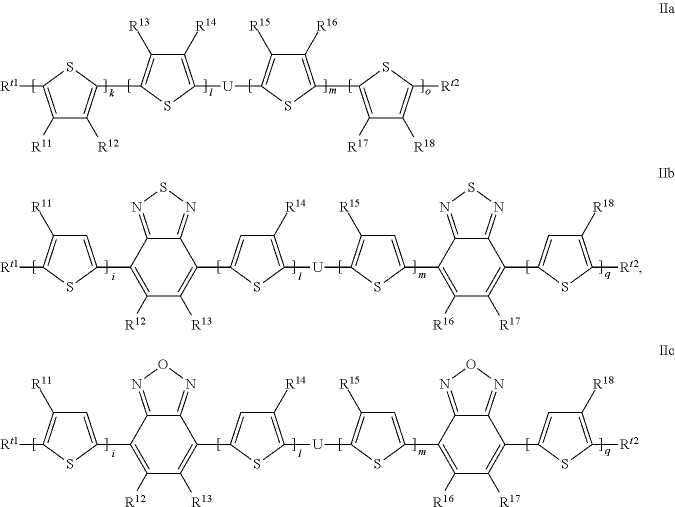

wherein U, R^{t1}, R^{t2}, R¹¹ to R¹⁸, i, k, l, m, o, q has one of the meanings as described above or preferably described above or below.

In a preferred embodiment of the invention, R¹¹ to R¹⁸ independently of each other denote H, halogen, straight-chain, branched or cyclic alkyl with 1 to 20 C atoms or a straight-chain or branched alkyloxy with 1 to 20 C atoms. In a particularly preferred embodiment of the invention, R¹¹ to R¹⁸ independently of each other denote H, n-hexyl, n-octyl, 2-ethylhexyl, dodecyl, n-octoxyl, 2-ethylhexoxyl, n-dedecoxyl.

In a preferred embodiment of the invention, R^{t1} and R^{t2} denote H, F, Cl, Br, —CN, —CF₃, —O—R⁰, —S—R⁰, —SO₂—R, —C(═O)—R⁰, —C(═O)—OR⁰, —O—C(═O)—R⁰, —C(═O)NR⁰R⁰⁰, —NR—C(═O)— R⁰⁰, —NR⁰R⁰⁰, —CR⁰═CR⁰⁰R⁰⁰⁰, —C≡C—R⁰, —SiR⁰R⁰⁰R⁰⁰⁰, —CH═C(CN)—C(O)—OR⁰, —CH═C(COOR⁰)(COOR⁰⁰), —CH═C(CONR⁰R⁰⁰)₂,

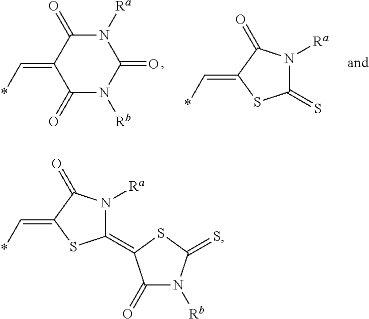

wherein R⁰, R⁰⁰, R⁰⁰⁰, R^{a} and R^{b} has one of the meanings as described or preferably described before.

In a preferred embodiment of the invention, i, k, l, m, o and q are 1.

The polymers of the present invention include homopolymers, statistical co-polymers, random co-polymers, alternating co-polymers and block co-polymers, and combinations of the aforementioned and are preferably formed by identical or different repeating units of formulae (III) to (IX).

Preferred repeating units for polymers according to the invention containing repeating units of formula (IV) correspond to formulae (IVa), (IVb), (IVc) and (IVd);

preferred repeating units for polymers according to the invention containing repeating units of formula (V) correspond to formulae (Va), (Vb), (Vc) and (Vd);
preferred repeating units for polymers according to the invention containing repeating units of formula (VI) correspond to formulae (VIa), (VIb), (VIc) and (VId);
preferred repeating units for polymers according to the invention containing repeating units of formula (VII) correspond to formulae (VIIa) and (VIIb),

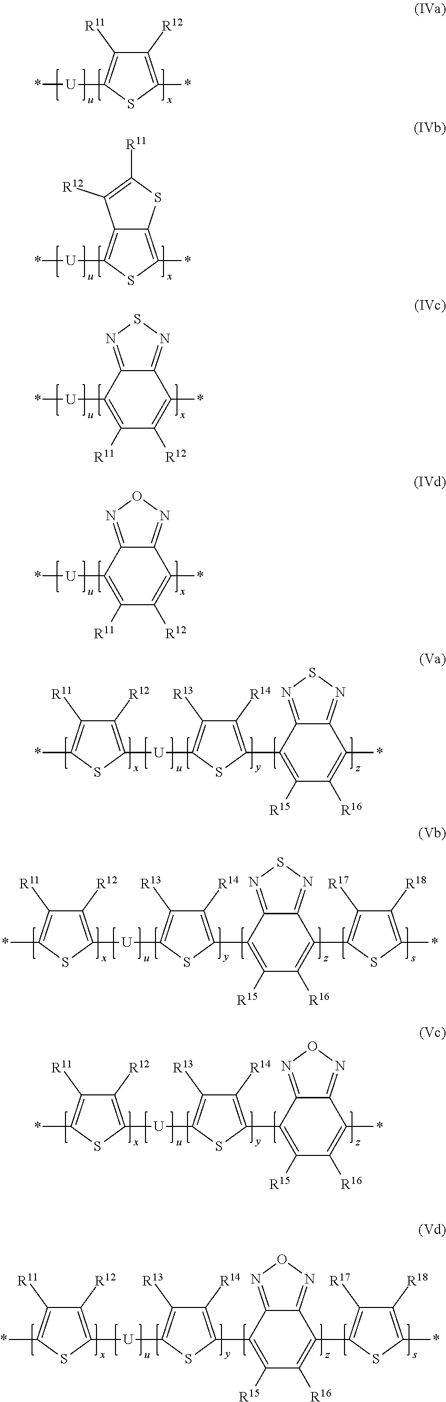

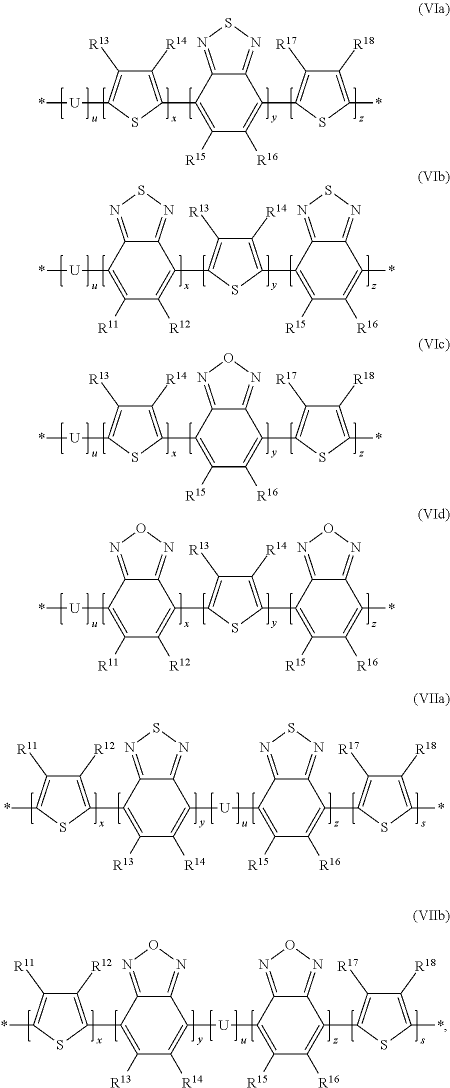

wherein U, R¹¹ to R¹⁸, u, x, y, z and s has one of the meanings as described above or preferably described above or below.

In a preferred embodiment, u, x, y, z and s preferably denote an integer ≥1, preferably 1, 2 or 3.

In a particularly preferred embodiment, the repeating units for polymers according to the invention containing repeating units of formula (Va) correspond to formulae (Ve), (Vf), (Vg) or (Vh):

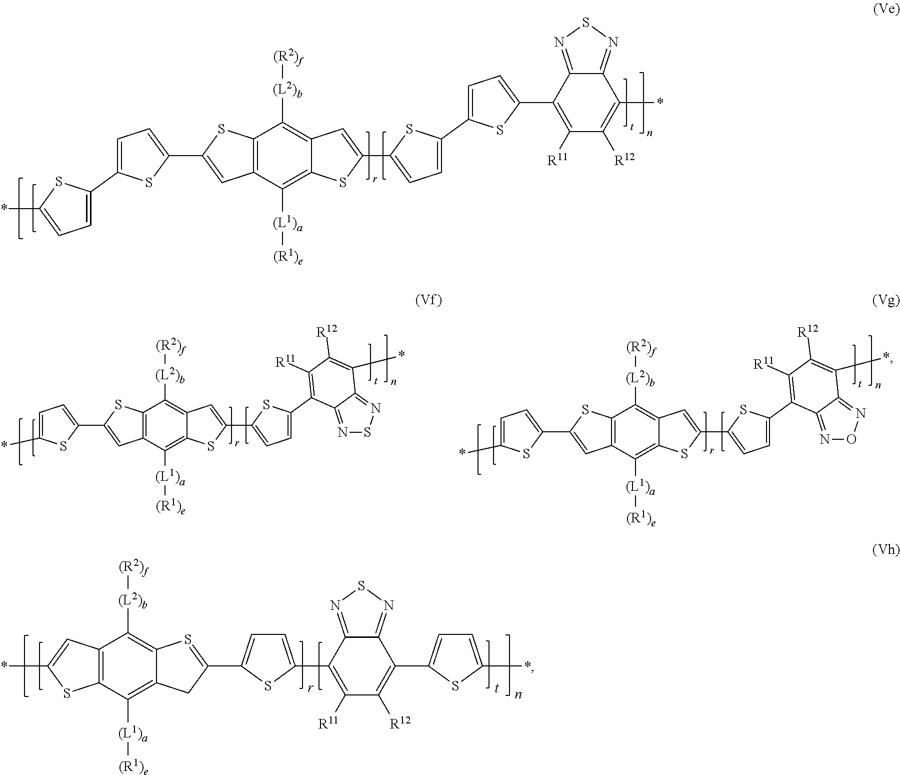

wherein R¹, R², L¹, L², a, b, e, f, R¹¹, R¹² have a meaning as described or preferably described before,
r and t denote indepentently of each other, and on each occurrence identically or differently a molar ratio from 0.01 to 0.99 and
n denotes an integer of ≥5, preferably ≥10, most preferably ≥20, and preferably up to 2000, very preferably up to 1000, most preferably up to 500, including any combination of the aforementioned lower and upper limits n.

In a very particularly preferred embodiment, the repeating units for polymers according to the invention containing or consisting of repeating units of formula (Vf) or (Vh), as described before.

In a preferred embodiment, r and t preferably denote a molar ratio from 0.2 to 0.8, very preferably a molar ration from 0.35 to 0.65.

M_{W} of the polymers according to the invention as described above is at least 5,000, preferably at least 8,000, very preferably at least 10,000, and preferably up to 300,000, very preferably up to 100,000.

The polymers according to the invention correspond to the formula R^{t1}-chain-R^{t2},

wherein “chain” are one or more repeating units according to formulae (III) to (IX), (IIIa) to (IIId), (IVa) to (IVd), (Va) to (Vh), (VIa) to (VId) or (VIIa) to (VIIb) or preferred repeating units as described before and wherein R^{t1} and R^{t2} have a meaning as described or preferably described above.

The oligomers and polymers of the present invention can be synthesized according to or in analogy to methods that are known to the skilled person and are described in the literature, e.g. WO 2011/131280 or WO 2011/085004. For example, they can be suitably prepared by aryl-aryl coupling reactions, such as Yamamoto coupling, Suzuki coupling, C—H activation coupling, Kumada coupling, Stille coupling, Sonogashira coupling, Heck coupling or Buchwald coupling. Suzuki coupling, C—H activiation coupling, Stille coupling and Yamamoto coupling are especially preferred.

The monomers which are polymerised to form the polymers or oligomers according to the invention can be prepared according to methods which are known to the person skilled in the art.

The process for preparing a polymer according to the invention comprises the step of coupling one or more identical or different monomers corresponding to the repeating units of formulae (I), (III) to (IX), (IIIa) to (IIId), (IVa) to (IVd), (Va) to (Vh), (VIa) to (VId) or (VIIa) to (VIIb) with one or more identical or different co-monomers of the formulae (I), (III) to (IX), (IIIa) to (IIId), (IVa) to (IVd), (Va) to (Vh), (VIa) to (VId) or (VIIa) to (VIIb) in a polymerisation reaction, preferably in an aryl-aryl coupling reaction.

Preferred methods for polymerisation are those leading to C—C-coupling or C—N-coupling, like Yamamoto coupling, Kumada coupling, Negishi coupling, Suzuki coupling, Stille coupling, Sonogashira coupling, Heck coupling, C—H activation coupling, Ullmann coupling or Buchwald coupling. Especially preferred are Suzuki coupling, C—H activation coupling, Negishi coupling, Stille coupling and Yamamoto coupling. Suzuki coupling is described for example in WO 00/53656 A1. Negishi coupling is described for example in J. Chem. Soc., Chem. Commun., 1977, 683-684. Yamamoto coupling is described in for example in T. Yamamoto et al., Prog. Polym. Sci., 1993, 17, 1153-1205, or WO 2004/022626 A1. Stille coupling is described for example in Z. Bao et al., J. Am. Chem. Soc., 1995, 117, 12426-12435. C—H activation is described for example for example in M. Leclerc et al, Angew. Chem. Int. Ed. 2012, 51, 2068-2071. For example, when using Yamamoto coupling, monomers having two reactive halide or sulfonate groups are preferably used. When using Suzuki coupling, monomers having two reactive boronic acid or boronic acid ester groups and two reactive halide groups are preferably used. When using Stille coupling, monomers having two reactive stannane groups and two reactive halide groups are preferably used. When using Negishi coupling, monomers having two reactive organozinc groups and two reactive halide groups are preferably used. When synthesizing a linear polymer by C—H activation polymerisation, preferably a monomer as described above is used wherein at least one reactive group is a activated hydrogen bond.

Suzuki, Stille or C—H activation coupling polymerisation may be used to prepare homopolymers as well as statistical, alternating and block random copolymers. Statistical, random block copolymers or block copolymers can be prepared for example from the above monomers, wherein one of the reactive groups is halogen and the other reactive group is a C—H activated bond, boronic acid, boronic acid derivative group or and alkylstannane. The synthesis of statistical, alternating and block copolymers is described in detail for example in WO 03/048225 A2 or WO 2005/014688 A2.

Preferred catalysts, especially for Suzuki, Negishi, C—H activation or Stille coupling, are selected from Pd(0) complexes or Pd(II) salts. Preferred Pd(0) complexes are those bearing at least one phosphine ligand such as Pd(Ph₃P)₄. Another preferred phosphine ligand is tris(ortho-tolyl)phosphine, i.e. Pd(o-Tol₃P)₄. Preferred Pd(II) salts include palladium acetate, i.e. Pd(OAc)₂ or trans-di(μ-acetato)-bis[o-(di-o-tolylphosphino)benzyl]dipalladium(II). Alternatively the Pd(0) complex can be prepared by mixing a Pd(0) dibenzylideneacetone complex, for example tris(dibenzyl-ideneacetone)dipalladium(0), bis(dibenzylideneacetone)palladium(0), or Pd(II) salts e.g. palladium acetate, with a phosphine ligand, for example triphenylphosphine, tris(ortho-tolyl)phosphine, tris(o-methoxyphenyl)phosphine or tri(tert-butyl)phosphine. Suzuki and C—H activiation polymerisation is performed in the presence of a base, for example sodium carbonate, potassium carbonate, cesium carbonated, lithium hydroxide, potassium phosphate or an organic base such as tetraethylammonium carbonate or tetraethylammonium hydroxide. Yamamoto polymerisation employs a Ni(0) complex, for example bis(1,5-cyclooctadienyl) nickel(0).

As alternatives to halogens as terminal end groups, leaving groups of formula —O—SO₂Z¹ can be used wherein Z¹ is selected from the group consisting of alkyl and aryl, each being optionally substituted, as described or preferably described above. Particular examples of such leaving groups are tosylate, mesylate and triflate.

Especially suitable and a preferred synthesis method for the monomers corresponding to the monomeric unit of formula (I) are exemplarily illustrated in Citterio et al., Tetrahedron 1996, 13227-13242, WO 2011/085004 A1, WO 2012/143077 A1, WO 2012/156022 A1, WO 2013/045014 A1, WO 2013/135339 A1 and WO 2013/142835 A1.

The polymers can be synthesized by various organometallic catalyzed reaction such as Yamamoto coupling (see e.g. Yamamoto, T.; Morita, A.; Miyazaki, Y.; Maruyama, T.; Wakayama, H.; Zhou, Z. H.; Nakamura, Y.; Kanbara, T.; Sasaki, S.; Kubota, K. Macromolecules 1992, 25, 1214-1223, and Yamamoto, T.; Takimiya, K. J. Am. Chem. Soc. 2007, 129, 2224-2225), Suzuki coupling (see e.g. Schlüter, A. D. J. Polym. Sci., Part A: Polym. Chem. 2001, 39, 1533-1556), Stille coupling (see e.g. Bao, Z.; Chan, W. K.; Yu, L. J. Am. Chem. Soc. 1995, 117, 12426-12435) or C—H activation (see e.g. M. Leclerc et al, Angew. Chem. Int. Ed. 2012, 51, 2068-2071). The below scheme 1 and 2 describe generic polymerisation combinations.

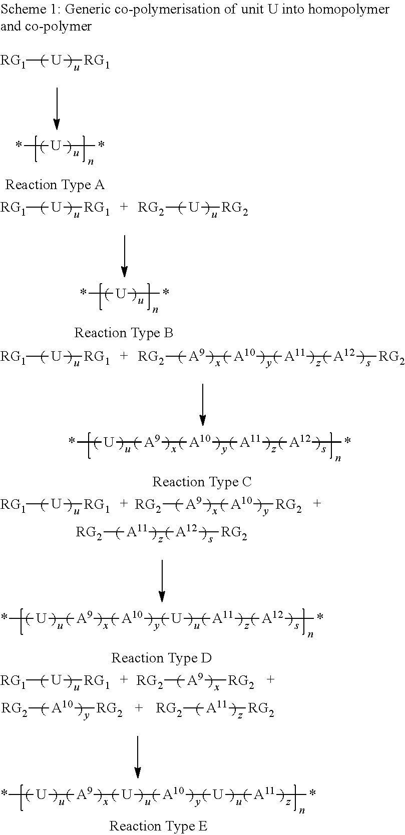

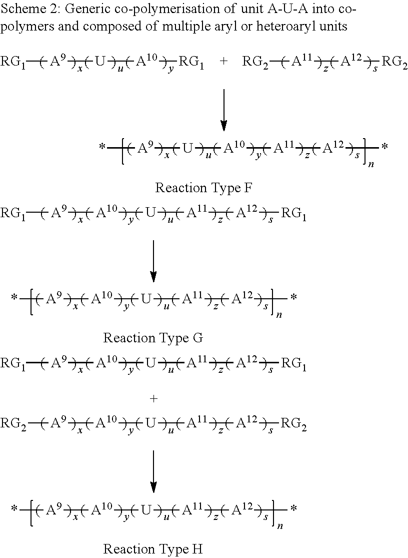

The homopolymers are preferably synthesized using Yamamoto as illustrated in Reaction Type A where RG₁ represent two reactive halide or sulfonate groups and Stille (where one RG₁ or alternatively RG₂ represents an alkyl stannane and RG₂ or alternatively RG₁ represent two reactive halide or sulfonate groups), C—H activation (where one RG₁ or alternatively RG₂ represents an activated C—H bond and RG₂ or alternatively RG₁ represent two reactive halide or sulfonate groups), or Suzuki coupling (where one RG₁ or alternatively RG₂ represents a borate and RG₂ or alternatively RG₁ represent two reactive halide or sulfonate groups), as illustrated in the Reaction type B.

Alternatived co-polymers are preferably synthesized using Stille (where one RG₁ or alternatively RG₂ represents an alkyl stannane and RG₂ or alternatively RG₁ represent two reactive halide or sulfonate groups), C—H activation (where one RG₁ or alternatively RG₂ represents an activated C—H bond and RG₂ or alternatively RG₁ represent two reactive halide or sulfonate groups), or Suzuki coupling (where one RG₁ or alternatively RG₂ represents a borate and RG₂ or alternatively RG₁ represent two reactive halide or sulfonate groups), as illustrated in the Reaction type C—H.

Random, statistical and block copolymers are preferably synthesized using Yamamoto (where both RG₁ and RG₂ are independently of each other two reactive halide or sulfonate groups), Stille (where one RG₁ or alternatively RG₂ represents an alkyl stannane and RG₂ or alternatively RG1 represent two reactive halide or sulfonate groups), C—H activation (where one RG₁ or alternatively RG₂ represents an activated C—H bond and RG₂ or alternatively RG₁ represent two reactive halide or sulfonate groups), or Suzuki coupling (where one RG₁ or alternatively RG₂ represents a borate and RG₂ or alternatively RG₁ represent two reactive halide or sulfonate groups), using at least one or more generic polymerisation reaction as illustrated in the Reaction types A-H and/or using an alternative reaction scheme excluding U containing monomers to form more complex polymer backbones.

There are no restrictions per se with respect to the choice of the light absorber material which is at least in part inorganic in the optoelectronic device according to the invention as described in detail above.

Preferably, the light absorber which is at least in part inorganic is a perovskite.

In one particularly preferred embodiment of the invention, the perovskite denotes a metal halide perovskite with the formula ABX₃,

where
A is a monovalent organic cation, a metal cation or a mixture of two or more of these cations
B is a divalent cation or a mixture of two or more of divalent cations and
X is F, Cl, Br, I, BF₄ or a combination thereof.

The invention therefore relates to an optoelectronic device as described or preferably described above wherein the perovskite denotes a metal halide perovskite with the formula ABX₃,

where
A is a monovalent organic cation, a metal cation or a mixture of two or more of these cations
B is a divalent cation or a mixture of two or more of divalent cations and
X is F, Cl, Br, I, BF₄ or a combination thereof.

In one particularly preferred embodiment of the invention, the perovskite denotes a metal halide perovskite with the formula ABX₃,

where
A is a monovalent organic cation, a metal cation or a mixture of two or more of these cations
B is a divalent cation and
X is F, Cl, Br, I, BF₄ or a combination thereof.

Preferably, the monovalent organic cation of the perovskite is selected from alkylammonium, wherein the alkyl group is straight-chain or branched having 1 to 6 C atoms, formamidinium or guanidinium or wherein the metal cation is selected from K⁺, Cs⁺ or Rb⁺.

The invention therefore relates to an optoelectronic device as described or preferably described above wherein the monovalent organic cation of the perovskite is selected from alkylammonium, wherein the alkyl group is straight-chain or branched having 1 to 6 C atoms, formamidinium or guanidinium or wherein the metal cation is selected from K⁺, Cs⁺ or Rb⁺.

Suitable divalent cations B are Ge²⁺, Sn²⁺ or Pb²⁺.

Suitable pervoskite materials are CsSnI₃, CH₃NH₃Pb(I₁₋ₓClₓ)₃, CH₃NH₃Pbl₃, CH₃NH₃Pb(I₁₋ₓBrₓ)₃, CH₃NH₃Pb(I₁₋ₓ(BF₄)ₓ)₃, (H₂N—CH═NH₂)Pb(I₁₋ₓClₓ)₃, (H₂N—CH═NH₂)Pbl₃, (H₂N—CH═NH₂)Pb(I₁₋ₓBrₓ)₃, (H₂N—CH═NH₂)_{y}(CH₃NH₃)_{(1-y)}Pb(I₁₋ₓBrₓ)₃, (H₂N—CH═NH₂)_{y}(CH₃NH₃)_{(1-y)}Pb(I₁₋ₓClₓ)₃, (H₂N—CH═NH₂)_{y}(CH₃NH₃)_{(1-y)}Pbl₃, Cs_{y}(CH₃NH₃)_{(1-y)}Pb(I₁₋ₓBrₓ)₃, Cs_{y}(CH₃NH₃)_{(1-y)}Pb(I₁₋ₓCₓ)₃, Cs_{y}(CH₃NH₃)_{(1-y)}PbI₃, CH₃NH₃Sn(I₁₋ₓClₓ)₃, CH₃NH₃SnI₃ or CH₃NH₃Sn(I₁₋ₓBrₓ)₃ wherein x and y are each independently defined as follows: (0<x≤1) and (0<y≤1). More generalizing, suitable perovskites may comprise two halides corresponding to formula Xa₍₃₋ₓ₎Xb₍ₓ₎, wherein Xa and Xb are each independently selected from Cl, Br, or I, and x is greater than 0 and less than 3.

Suitable pervoskites are also disclosed in WO 2013/171517, claims 52 to 71 and claims 72 to 79, which is entirely incorporated herein by reference. The materials are defined as mixed-anion perovskites comprising two or more different anions selected from halide anions and chalcogenide anions.

Preferred perovskites are disclosed on page 18, lines 5 to 17. As described, the perovskite is usually selected from CH₃NH₃PbBrl₂, CH₃NH₃PbBrCl₂, CH₃NH₃PblBr₂, CH₃NH₃PblCl₂, CH₃NH₃SnF₂Br, CH₃NH₃SnF₂I and (H₂N═CH—NH₂)Pbl_{3z}Br_{3(1-z)}, wherein z is greater than 0 and less than 1.

The optoelectronic device architecture, preferably the PSC device architecture, according to the invention can be for example of any type known from the literature.

A first preferred optoelectronic device architecture, preferably PSC device architecture, according to the invention comprises the following layers (in the sequence from bottom to top):
optionally a substrate, that, in any combination, can be flexible or rigid and transparent, semi-transparent or non-transparent and electrically conductive or non-conductive;
a high work function electrode, preferably comprising a doped metal oxide, for example fluorine-doped tin oxide (FTO), tin-doped indium oxide (ITO), or aluminium-doped zinc oxide;
optionally an electron-selective layer, that, in some cases, can be a dense layer and/or be composed of nanoparticles, and that preferably comprises a metal oxide such as TiO₂, ZnO₂, SnO₂, Y₂O₅, Ga₂O₃, SrTiO₃, BaTiO₃ or combinations thereof;
optionally, a porous scaffold that can be conducting, semi-conducting or insulating and that preferably comprises a metal oxide such as TiO₂, ZnO₂, SnO₂, Y₂O₅, Ga₂O₃, SrTiO₃, BaTiO₃, Al₂O₃, ZrO₂, SiO₂ or combinations thereof and that preferably can be composed of nanoparticles, nanorods, nanoflakes, nanotubes or nanocolumns;
a layer comprising a light absorber which is at least in part inorganic, particularly preferably a metal halide perovskite as described or preferably described above,
   that, in some cases, can be a dense or porous layer and that optionally can partly or fully infiltrate into the underlying layer;
a hole selective layer, that comprises one or more hole-transporting materials, out of which at least one is a compound, oligomer or polymer comprising at least one monomeric unit according to formula (I) or a preferred embodiment as described above, and that, in some cases, can comprise additives such as lithium salts, for example LiY, where Y is a monovalent organic anion, preferably bis(trifluoromethylsulfonyl)imide, tertiary amines such as 4-tert-butylpyridine, or any other covalent or ionic compounds, for example tris(2-(1H-pyrazol-1-yl)-4-tert-butylpyridine)-cobalt(III) tris(bis(trifluoromethylsulfonyl)imide)), that can enhance the properties of the hole selective layer, for example the electrical conductivity, and/or facilitate its processing;
   and a back electrode that can be metallic, for example made of Au, Ag, Al, Cu, Ca, Ni or combinations thereof, or non-metallic and transparent, semi-transparent or non-transparent.

A second preferred optoelectronic device architecture, preferably PSC device architecture, according to the invention comprises the following layers (in the sequence from bottom to top):
optionally a substrate, that, in any combination, can be flexible or rigid and transparent, semi-transparent or non-transparent and electrically conductive or non-conductive;
a high work function electrode, preferably comprising a doped metal oxide, for example fluorine-doped tin oxide (FTO), tin-doped indium oxide (ITO), or aluminium-doped zinc oxide;
optionally a hole injection layer, that, for example, changes the work function of the underlying electrode, and/or modifies the surface of the underlying layer and/or helps to planarize the rough surface of the underlying layer and that, in some cases, can be a monolayer;
a hole selective layer, that comprises one or more hole-transporting materials, out of which at least one is a compound, oligomer or polymer comprising at least one monomeric unit according to formula (I) or a preferred embodiment as described above, and that, in some cases, can comprise additives such as lithium salts, for example LiY, where Y is a monovalent organic anion, preferably bis(trifluoromethylsulfonyl)imide, tertiary amines such as 4-tert-butylpyridine, or any other covalent or ionic compounds, for example tris(2-(1H-pyrazol-1-yl)-4-tert-butylpyridine)-cobalt(II) tris(bis(trifluoromethylsulfonyl)imide)), that can enhance the properties of the hole selective layer, for example the electrical conductivity, and/or facilitate its processing;
a layer comprising a light absorber which is at least in part inorganic, particularly preferably a metal halide perovskite as described or preferably described above;
optionally an electron-selective layer, that, in some cases, can be a dense layer and/or be composed of nanoparticles, and that, for example, can comprise a metal oxide such as TiO₂, ZnO₂, SnO₂, Y₂O₅, Ga₂O₃, SrTiO₃, BaTiO₃ or combinations thereof, and/or that can comprise a substituted fullerene, for example [6,6]-phenyl C61-butyric acid methyl ester, and/or that can comprise a molecular, oligomeric or polymeric electron-transport material, for example 2,9-Dimethyl-4,7-diphenyl-1,10-phenanthroline, or a mixture thereof;
   and a back electrode that can be metallic, for example made of Au, Ag, Al, Cu, Ca, Ni or combinations thereof, or non-metallic and transparent, semi-transparent or non-transparent.

To produce hole selective layers in devices according to the invention, preferably PSC devices, the compounds, oligomers or polymers comprising at least one monomeric unit according to formula (I) or preferred embodiments as described above optionally together with other compounds or additives in the form of blends or mixtures may be deposited by any suitable method. Liquid coating of devices is more desirable than vacuum deposition techniques. Solution deposition methods are especially preferred. Formulations comprising the compounds, oligomers or polymers comprising at least one monomeric unit according to formula (I) or preferred embodiments as described above enable the use of a number of liquid coating techniques. Preferred deposition techniques include, without limitation, dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, curtain coating, brush coating, slot die coating or pad printing. For the fabrication of PSC devices and modules, deposition techniques for large area coating are preferred, for example slot die coating or spray coating.

Formulations that can be used to produce hole selective layers in optoelectronic devices according to the invention, preferably in PSC devices comprise one or more compounds, oligomers or polymers comprising at least one monomeric unit according to formula (I) or preferred embodiments as described above in the form of blends or mixtures optionally together with one or more further hole transport materials and/or electron blocking materials and/or binders and/or other additives as described above and below, and one or more solvents.

The formulation may include or comprise, essentially consist of or consist of the said necessary or optional constituents as described above or below. All compounds or components which can be used in the formulations are either known and commercially available or can be synthesised by known processes.

Solvents used for this purpose are generally organic solvents. Typical organic solvents can be aromatic solvents, halogenated solvents or chlorinated solvents, including chlorinated aromatic solvents. Preferred solvents are aliphatic hydrocarbons, chlorinated hydrocarbons, aromatic hydrocarbons, ketones, ethers and mixtures thereof. Additional solvents which can be used include 1,2,4-trimethylbenzene, 1,2,3,4-tetra-methyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, N,N-dimethylformamide, 2-chloro-6-fluorotoluene, 2-fluoroanisole, anisole, 2,3-dimethylpyrazine, 4-fluoroanisole, 3-fluoroanisole, 3-trifluoro-methylanisole, 2-methylanisole, phenetol, 4-methylanisole, 3-methylanisole, 4-fluoro-3-methylanisole, 2-fluorobenzonitrile, 4-fluoroveratrol, 2,6-dimethylanisole, 3-fluorobenzo-nitrile, 2,5-dimethylanisole, 2,4-dimethylanisole, benzonitrile, 3,5-dimethyl-anisole, N,N-dimethylaniline, ethyl benzoate, 1-fluoro-3,5-dimethoxy-benzene, 1-methylnaphthalene, N-methylpyrrolidinone, 3-fluorobenzo-trifluoride, benzotrifluoride, dioxane, trifluoromethoxy-benzene, 4-fluorobenzotrifluoride, 3-fluoropyridine, toluene, 2-fluoro-toluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chlorofluoro-benzene, 1-chloro-2,5-difluorobenzene, 4-chlorofluorobenzene, chloro-benzene, o-dichlorobenzene, 2-chlorofluorobenzene, p-xylene, m-xylene, o-xylene or mixture of o-, m-, and p-isomers. Solvents with relatively low polarity are generally preferred. For inkjet printing, gravure printing, doctor blade coating, roller printing, reverse-roller printing, offset lithography printing, dry offset lithography printing, flexographic printing, web printing, spray coating, curtain coating, brush coating and slot die coating, solvents and solvent mixtures with high boiling temperatures are preferred. For spin coating alkylated benzenes like xylene and toluene are preferred.

Examples of especially preferred solvents include, without limitation, dichloromethane, trichloromethane, tetrachloromethane, chlorobenzene, o-dichlorobenzene, 1,2,4-trichlorobenzene, 1,2-dichloroethane, 1,1,1-trichloroethane, 1,1,2,2-tetrachloroethane, 1,8-diiodooctane, 1-chloronaphthalene, 1,8-octane-dithiol, anisole, 2,5-di-methylanisole, 2,4-dimethylanisole, toluene, o-xylene, m-xylene, p-xylene, mixture of o-, m-, and p-xylene isomers, 1,2,4-trimethylbenzene, mesitylene, cyclohexane, 1-methylnaphthalene, 2-methylnaphthalene, 1,2-dimethylnaphthalene, tetraline, decaline, indane, 1-methyl-4-(1-methylethenyl)-cyclohexene (d-Limonene), 6,6-dimethyl-2-methylenebicyclo[3.1.1]heptanes (β-pinene), methyl benzoate, ethyl benzoate, nitrobenzene, benzaldehyde, tetrahydrofuran, 1,4-dioxane, 1,3-dioxane, morpholine, acetonitrile, acetone, methylethylketone, ethyl acetate, n-butyl acetate, N,N-dimethylformamide, dimethylacetamide, dimethylsulfoxide and/or mixtures thereof.

A binder to be used in the formulation as described before, which is preferably a polymer, may comprise either an insulating binder or a semiconducting binder, or mixtures thereof, may be referred to herein as the organic binder, the polymeric binder or simply the binder.

Preferably, the polymeric binder comprises a weight average molecular weight in the range of 1000 to 5,000,000 g/mol, especially 1500 to 1,000,000 g/mol and more preferable 2000 to 500,000 g/mol. Surprising effects can be achieved with polymers having a weight average molecular weight of at least 10000 g/mol, more preferably at least 100000 g/mol.

In particular, the polymer can have a polydispersity index M_{w}/Mₙ in the range of 1.0 to 10.0, more preferably in the range of 1.1 to 5.0 and most preferably in the range of 1.2 to 3.

Preferably, the inert binder is a polymer having a glass transition temperature in the range of −70 to 160° C., preferably 0 to 150° C., more preferably 50 to 140° C. and most preferably 70 to 130° C. The glass transition temperature can be determined by measuring the DSC of the polymer (DIN EN ISO 11357, heating rate 10° C. per minute).

The weight ratio of the polymeric binder to the charge transport materials is preferably in the range of 30:1 to 1:30, particularly in the range of 5:1 to 1:20 and more preferably in the range of 1:2 to 1:10.

According to a special embodiment the binders preferably comprise repeating units derived from styrene and/or olefins. Preferred polymeric binders can comprise at least 80%, preferably 90% and more preferably 99% by weight of repeating units derived from styrene monomers and/or olefins.

Styrene monomers are well known in the art. These monomers include styrene, substituted styrenes with an alkyl substituent in the side chain, such as α-methylstyrene and α-ethylstyrene, substituted styrenes with an alkyl substituent on the ring such as vinyltoluene and p-methylstyrene, halogenated styrenes such as monochlorostyrenes, dichlorostyrenes, tribromostyrenes and tetrabromostyrenes.

Olefins are monomers consisting of hydrogen and carbon atoms. These monomers include ethylene, propylene, butylenes, isoprene and 1,3-butadiene.

According to a special aspect of the present invention, the polymeric binder is polystyrene having a weight average molecular weight in the range of 50,000 to 2,000,000 g/mol, preferably 100,000 to 750,000 g/mol, more preferably in the range of 150,000 to 600,000 g/mol and most preferably in the range of 200,000 to 500,000 g/mol.

Further examples of suitable binders are disclosed for example in US 2007/0102696 A1. Especially suitable and preferred binders are described in the following.

The binder should preferably be capable of forming a film, more preferably a flexible film.

Suitable polymers as binders include poly(1,3-butadiene), polyphenylene, polystyrene, poly(c-methylstyrene), poly(c-vinylnaphtalene), poly(vinyltoluene), polyethylene, cis-polybutadiene, polypropylene, polyisoprene, poly(4-methyl-1-pentene), poly (4-methylstyrene), poly(chorotrifluoroethylene), poly(2-methyl-1,3-butadiene), poly(p-xylylene), poly(α-α-α′-α′ tetrafluoro-p-xylylene), poly[1,1-(2-methyl propane)bis(4-phenyl)carbonate], poly(cyclohexyl methacrylate), poly(chlorostyrene), poly(2,6-dimethyl-1,4-phenylene ether), polyisobutylene, poly(vinyl cyclohexane), poly(vinylcinnamate), poly(4-vinylbiphenyl), 1,4-Polyisoprene, Polynorbornene, Poly(styrene-block-butadiene); 31% wt styrene, Poly(styrene-block-butadiene-block-styrene);

30% wt styrene, Poly(styrene-co-maleic anhydride) (and ethylene/butylene) 1-1.7% maleic anhydride, Poly(styrene-block-ethylene/butylene-block-styrene) triblock polymer 13% styrene, Poly(styrene-block-ethylene-propylene-block-styrene) triblock polymer 37% wt styrene, Poly(styrene-block-ethylene/butylene-block-styrene) triblock polymer 29% wt styrene, Poly(1-vinylnaphthalene) Poly(1-vinylpyrrolidone-co-styrene) 64% styrene, Poly(1-vinylpyrrolidone-co-vinyl acetate) 1.3:1, Poly(2-chlorostyrene), Poly(2-vinylnaphthalene) Poly(2-vinylpyridine-co-styrene) 1:1, Poly(4,5-Difluoro-2,2-bis(CF3)-1,3-dioxole-co-tetrafluoroethylene) Teflon, Poly(4-chlorostyrene), Poly(4-methyl-1-pentene), Poly(4-methylstyrene) Poly(4-vinylpyridine-co-styrene) 1:1, Poly(alpha-methylstyrene) Poly(butadiene-graft-poly(methyl acrylate-co-acrylonitrile)) 1:1:1, Poly(butyl methacrylate-co-isobutyl methacrylate) 1:1, Poly(butyl methacrylate-co-methyl methacrylate) 1:1, Poly(cyclohexylmethacrylate) Poly(ethylene-co-1-butene-co-1-hexene) 1:1:1, Poly(ethylene-co-ethylacrylate-co-maleic anhydride); 2% anhydride, 32% ethyl acrylate, Poly(ethylene-co-glycidyl methacrylate) 8% glycidyl methacrylate, Poly(ethylene-co-methyl acrylate-co-glycidyl meth-acrylate) 8% glycidyl metha-crylate 25% methyl acrylate Poly(ethylene-co-octene) 1:1, Poly(ethylene-co-propylene-co-5-methylene-2-norbornene) 50% ethylene, Poly(ethylene-co-tetrafluoroethylene) 1:1 Poly(isobutyl methacrylate), Poly(isobutylene), Poly(methyl methacrylate)-co-(fluorescein O-methacrylate) 80% methyl methacrylate, Poly(methyl methacrylate-co-butyl methacrylate) 85% methyl methacrylate, Poly(methyl methacrylate-co-ethyl acrylate) 5% ethyl acrylate, Poly(propylene-co-butene) 12% 1-butene, Poly(styrene-co-allyl alcohol) 40% allyl alcohol, Poly(styrene-co-maleic anhydride) 7% maleic anhydride, Poly(styrene-co-maleic anhydride) cumene terminated (1.3:1), Poly(styrene-co-methyl methacrylate) 40% styrene, Poly(vinyltoluene-co-alpha-methylstyrene) 1:1, Poly-2-vinylpyridine, Poly-4-vinylpyridine, Poly-alpha-pinene, ), Polymethyl methacrylate, Polybenzylmethacrylate, Polyethylmethacrylate, Polyethylene Polyethylene terephthalate, Polyethylene-co-ethylacrylate 18% ethyl acrylate, Polyethylene-co-vinylacetate 12% vinyl acetate, Polyethylene-graft-maleic anhydride 0.5% maleic anhydride, Polypropylene, Polypropylene-graft-maleic anhydride 8-10% maleic anhydride, Polystyrene Poly(styrene-block-ethylene/butylene-block-styrene) graft maleic anhydride 2% maleic anhydride 1:1:1 others, Poly(styrene-block-butadiene) branched 1:1, Poly(styrene-block-butadiene-block-styrene), 30% styrene, Poly(styrene-block-isoprene) 10% wt styrene, Poly(styrene-block-isoprene-block-styrene) 17% wt styrene, Poly(styrene-co-4-chloromethylstyrene-co-4-methoxymethylstyrene 2:1:1, Polystyrene-co-acrylonitrile 25% acrylonitrile, Polystyrene-co-alpha-methylstyrene 1:1, Polystyrene-co-butadiene 4% butadiene, Polystyrene-co-butadiene 45% styrene, Polystyrene-co-chloromethylstyrene 1:1, Polyvinylchloride Polyvinylcinnamate, Polyvinylcyclohexane, Polyvinylidenefluoride, Polyvinylidenefluoride-co-hexafluoropropylene assume 1:1, Poly(styrene-block-ethylene/propylene-block-styrene) 30% styrene, Poly(styrene-block-ethylene/propylene-block-styrene) 18% styrene, Poly(styrene-block-ethylene/propylene-block-styrene) 13% styrene, Poly(styrene-block ethylene block-ethylene/propylene-block styrene) 32% styrene, Poly(styrene-block ethylene block-ethylene/propylene-block styrene); 30% styrene, Poly(styrene-block-ethylene/butylene-block-styrene) 31% styrene, Poly(styrene-block-ethylene/butylene-block-styrene) 34% styrene, Poly(styrene-block-ethylene/butylene-block-styrene) 30% styrene, Poly(styrene-block-ethylene/butylene-block-styrene) 60%, styrenebranched or non-branched polystyrene-block-polybutadiene, polystyrene-block(polyethylene-ran-butylene)-block-polystyrene, polystyrene-block-polybutadiene-block-polystyrene, polystyrene-(ethylene-propylene)-diblock-copolymers (e.g. KRATON®-G1701E, Shell), poly(propylene-co-ethylene) and poly(styrene-co-methylmethacrylate).

Copolymers containing the repeat units of the above polymers are also suitable as binders. Copolymers offer the possibility of improving compatibility with the compounds, oligomers or polymers comprising at least one monomeric unit according to formula (I), modifying the morphology and/or the glass transition temperature of the final layer composition. It will be appreciated that in the above list certain materials are insoluble in commonly used solvents for preparing the layer. In these cases analogues can be used as copolymers.

Preferred insulating binders to be used in the formulations as described before are polystryrene, poly(α-methylstyrene), polyvinylcinnamate, poly(4-vinylbiphenyl), poly(4-methylstyrene), and polymethyl methacrylate. Most preferred insulating binders are polystyrene and polymethyl methacrylate.

The binder can also be selected from crosslinkable binders, like e.g. acrylates, epoxies, vinylethers, thiolenes etc. The binder can also be mesogenic or liquid crystalline.

The organic binder may itself be a semiconductor, in which case it will be referred to herein as a semiconducting binder. The semiconducting binder is still preferably a binder of low permittivity as herein defined.

Semiconducting binders for use in the present invention preferably have a number average molecular weight (Mₙ) of at least 1500-2000, more preferably at least 3000, even more preferably at least 4000 and most preferably at least 5000. The semiconducting binder preferably has a charge carrier mobility, μ, of at least 10⁻⁵ cm²V⁻¹s⁻¹, more preferably at least 10⁻⁴ cm²V⁻¹s⁻¹.

A preferred semiconducting binder comprises a homo-polymer or copolymer (including block-copolymer) containing arylamine (preferably triarylamine).

Suitable solvents for the ingredients can be determined by preparing a contour diagram for the material as described in ASTM Method D 3132 at the concentration at which the mixture will be employed. The material is added to a wide variety of solvents as described in the ASTM method.

Suitable further hole transport materials are well-known in the art. Preferred hole transport materials for combination are spiro-OMeTAD, 2,2′,7,7′-tetrakis-(N,N′-di-4-methoxy-3,5-dimethylphenylamine)-9,9′-spirofluorene, tris(p-anisyl)amine, N,N,N′,N′-tetrakis(4-methoxyphenyl)-1,1′-biphenyl-4,4′diamine, 2,7-bis[N,N-bis(4-methoxy-phenyl)amino]-9,9-spirobifluorene, poly(3-hexylthiophene) (P3HT), poly(3,4-ethylenedioxythiophene)-poly(styrenesulfonate) (PEDOT:PSS), poly[bis(4-phenyl)(2,4,6-trimethylphenyl)amine] (PTAA), NiO and V₂O₅.

The formulation as described before may be prepared by a process which comprises:
(i) first mixing a compound, oligomer or polymer comprising at least one monomeric unit according to formula (I) as described before or preferably described before, optionally a binder or a precursor of a binder as described before, optionally a further hole transport material, optionally one or more further additives a described below and a solvent or solvent mixture as described before and
(ii) applying such mixture to a substrate; and optionally evaporating the solvent(s) to form a hole selective layer according to the present invention.

In step (i) the solvent may be a single solvent for the compound, oligomer or polymer comprising at least one monomeric unit according to formula (I) as described before or preferably described before and the organic binder and/or further hole transport material may each be dissolved in a separate solvent followed by mixing the resultant solutions to mix the compounds.

Alternatively, the binder may be formed in situ by mixing or dissolving a compound, oligomer or polymer comprising at least one monomeric unit according to formula (I) as described before or preferably described before in a precursor of a binder, for example a liquid monomer, oligomer or crosslinkable polymer, optionally in the presence of a solvent, and depositing the mixture or solution, for example by dipping, spraying, painting or printing it, on a substrate to form a liquid layer and then curing the liquid monomer, oligomer or crosslinkable polymer, for example by exposure to radiation, heat or electron beams, to produce a solid layer. If a preformed binder is used it may be dissolved together with the compound, oligomer or polymer comprising at least one monomeric unit according to formula (I) as described before or preferably described before in a suitable solvent as described before, and the solution deposited for example by dipping, spraying, painting or printing it on a substrate to form a liquid layer and then removing the solvent to leave a solid layer. It will be appreciated that solvents are chosen which are able to dissolve all ingredients of the formulation, and which upon evaporation from the solution blend give a coherent defect free layer.

Besides the said components, the formulation as described before may comprise further additives and processing assistants. These include, inter alia, surface-active substances (surfactants), lubricants and greases, additives which modify the viscosity, additives which increase the conductivity, dispersants, hydrophobicising agents, adhesion promoters, flow improvers, antifoams, deaerating agents, diluents, which may be reactive or unreactive, fillers, assistants, processing assistants, dyes, pigments, stabilisers, sensitisers, nanoparticles and inhibitors.

Additives can be used to enhance the properties of the hole selective layer and/or the properties of any of the neighbouring layers and/or the performance of the optoelectronic device according to the invention. Additives can also be used to facilitate the deposition, the processing or the formation of the hole selective layer and/or the deposition, the processing or the formation of any of the neighbouring layers. Preferably, one or more additives are used which enhance the electrical conductivity of the electron selective layer and/or passivate the surface of any of the neighbouring layers.

Suitable methods to incorporate one or more additives include, for example exposure to a vapor of the additive at atmospheric pressure or at reduced pressure, mixing a solution or solid containing one or more additives and a material or a formulation as described or preferably described before, bringing one or more additives into contact with a material or a formulation as described before, by thermal diffusion of one or more additives into a material or a formulation as described before, or by ion-implantantion of one or more additives into a material or a formulation as described before.

Additives used for this purpose can be organic, inorganic, metallic or hybrid materials. Additives can be molecular compounds, for example organic molecules, salts, ionic liquids, coordination complexes or organometallic compounds, polymers or mixtures thereof. Additives can also be particles, for example hybrid or inorganic particles, preferably nanoparticles, or carbon based materials such as fullerenes, carbon nanotubes or graphene flakes.

Examples for additives that can enhance the electrical conductivity are for example halogens (e.g. I₂, Cl₂, Br₂, ICl, ICl₃, IBr and IF), Lewis acids (e.g. PF₅, AsF₅, SbF₅, BF₃, BCl₃, SbCl₅, BBr₃ and SO₃), protonic acids, organic acids, or amino acids (e.g. HF, HCl, HNO₃, H₂SO₄, HClO₄, FSO₃H and ClSO₃H), transition metal compounds (e.g. FeCl₃, FeOCl, Fe(ClO₄)₃, Fe(4-CH₃C₆H₄SO₃)₃, TiCl₄, ZrCl₄, HfCl₄, NbF₅, NbCl₅, TaCl₅, MoF₅, MoCl₅, WF₅, WCl₆, UF₆ and LnCl₃ (wherein Ln is a lanthanoid)), anions (e.g. Cl⁻, Br⁻, I⁻, I₃⁻, HSO₄⁻, SO₄²⁻, NO₃⁻, ClO₄⁻, BF₄⁻, PF₆⁻, AsF₆⁻, SbF₆⁻, FeCl₄—, Fe(CN)₆³⁻, and anions of various sulfonic acids, such as aryl-SO₃⁻), cations (e.g. H⁺, Li⁺, Na⁺, K⁺, Rb⁺, Cs⁺, Co³⁺ and Fe³⁺), O₂, redox active salts (e.g. XeOF₄, (NO₂⁺) (SbF₆⁻), (NO₂⁺) (SbCl₆⁻), (NO₂⁺) (BF₄⁻), NOBF₄, NOPF₆, AgClO₄, H₂IrCl₆ and La(NO₃)₃.6H₂O), strongly electron-accepting organic molecules (e.g. 2,3,5,6-tetrafluoro-7,7,8,8-tetracyanoquinodimethane (F4-TCNQ)), transition metal oxides (e.g. WO₃, Re₂O₇ and MoO₃), metal-organic complexes of cobalt, iron, bismuth and molybdenum, (p-BrC₆H₄)₃NSbCl₆, bismuth(III) tris(trifluoroacetate), FSO₂OOSO₂F, acetylcholine, R₄N⁺, (R is an alkyl group), R₄P⁺ (R is a straight-chain or branched alkyl group 1 to 20), R₆As⁺ (R is an alkyl group), R₃S⁺ (R is an alkyl group) and ionic liquids (e.g. 1-Ethyl-3-methylimidazolium bis(trifluoromethylsulfonyl)imide). Suitable cobalt complexes beside of tris(2-(1H-pyrazol-1-yl)-4-tert-butylpyridine)-cobalt(III) tris(bis(trifluoromethylsulfonyl)imide)) are cobalt complex salts as described in WO 2012/114315, WO 2012/114316, WO 2014/082706, WO 2014/082704, EP 2883881 or JP 2013-131477.

Suitable lithium salts are beside of lithium bis(trifluoromethylsulfonyl)imide, lithium tris(pentafluoroethyl)trifluorophosphate, lithium dicyanamide, lithium methylsulfate, lithium trifluormethanesulfonate, lithium tetracyanoborate, lithium dicyanamide, lithium tricyanomethide, lithium thiocyanate, lithium chloride, lithium bromide, lithium iodide, lithium hexafluoroposphate, lithium tetrafluoroborate, lithium perchlorate, lithium hexafluoroantimonate, lithium hexafluoroarsenate or a combination of two or more. A preferred lithium salt is lithium bis(trifluoromethylsulfonyl)imide.

Preferably, the formulation comprises from 0.1 mM to 50 mM, preferably from 5 to 20 mM of the lithium salt.

Suitable device structures for devices comprising the compounds, oligomers or polymers comprising at least one monomeric unit according to formula (I) or preferred embodiments as described above and a mixed halide perovskite are described in WO 2013/171517, claims 52 to 71 and claims 72 to 79, which is entirely incorporated herein by reference.

Suitable device structures for devices comprising the compounds, oligomers or polymers comprising at least one monomeric unit according to formula (I) or preferred embodiments as described above and a dielectric scaffold together with a perovskite are described in WO 2013/171518, claims 1 to 90 or WO 2013/171520, claims 1 to 94 which are entirely incorporated herein by reference.

Suitable device structures for devices comprising the compounds, oligomers or polymers comprising at least one monomeric unit according to formula (I) or preferred embodiments as described above, a semiconductor and a perovskite are described in WO 2014/020499, claims 1 and 3 to 14, which is entirely incorporated herein by reference The surface-increasing scaffold structure described therein comprises nanoparticles which are applied and/or fixed on a support layer, e.g. porous TiO₂.

Suitable device structures for devices comprising the compounds, oligomers or polymers comprising at least one monomeric unit according to formula (I) or preferred embodiments as described above and comprising a planar heterojunction are described in WO 2014/045021, claims 1 to 39, which is entirely incorporated herein by reference. Such a device is characterized in having a thin film of a light-absorbing or light-emitting perovskite disposed between n-type (electron conducting) and p-type (hole-conducting) layers. Preferably, the thin film is a compact thin film.

Additionally, the invention relates to a method of preparing an optoelectronic device as described or preferably described before, the method comprising the steps of:
providing a first and a second electrode;
providing a hole selective layer comprising the compounds, oligomers or polymers comprising at least one monomeric unit according to formula (I) or preferred embodiments as described above according to the invention as described before.

The invention relates furthermore to a multijunction device comprising at least one device according to the invention as described before or preferably described before. Preferably, the multijunction device is a multijunction solar cell.

Preferably, the multijunction device is a tandem device.

The invention relates furthermore to a tandem device comprising at least one device according to the invention as described before or preferably described before. Preferably, the tandem device is a tandem solar cell.

The multijunction device or multijunction solar cell according to the invention may have two or more semi-cells wherein one of the semi cells comprises the compounds, oligomers or polymers in the active layer as described or preferably described above. There exists no restriction for the choice of the other type of semi cell which may be any other type of device or solar cell known in the art.

There are two different types of multijunction solar cells known in the art. The so called 2-terminal or monolithic multijunction solar cells have only two connections. The two or more subcells (or synonymously semi cells) are connected in series. Therefore, the current generated in both subcells is identical (current matching). The gain in power conversion efficiency is due to an increase in voltage as the voltages of the subcells add up.

The other type of multijunction solar cells is the so called 4-terminal or stacked multijunction solar cell. In this case, two or more subcells are operated independently. Therefore, two or more subcells can be operated at different voltages and can also generate different currents. The power conversion efficiency of the multijunction solar cell is the sum of the power conversion efficiencies of the combined subcells.

The invention furthermore relates to a module comprising a device according to the invention as described before or preferably described before.

The invention furthermore relates to a module comprising a plurality of devices according to the invention as described before or preferably described before.

It will be appreciated that variations to the foregoing embodiments of the invention can be made while still falling within the scope of the invention. Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

The invention will now be described in more detail by reference to the following examples, which are illustrative only and do not limit the scope of the invention.

### A) Preparation Examples

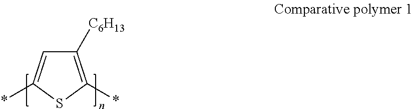

Comparative polymer 1 (Poly-2,5-(3-hexyl-thiophene)) is sourced from Merck KGaA.

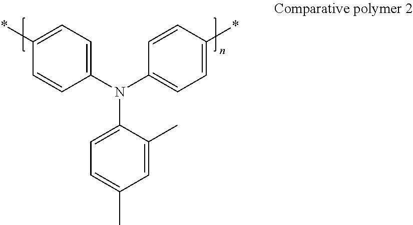

Comparative polymer 2 is sourced from EM Index Co., Ltd.

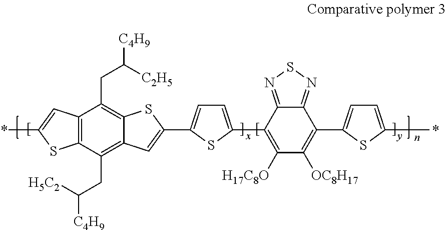

Comparative polymer 3 and its preparation is disclosed in WO 2011/131280, example 5, pages 61 and 62.

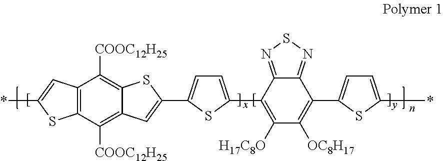

Polymer 1 and its preparation is disclosed in WO 2011/131280, example 11, pages 68 and 69.

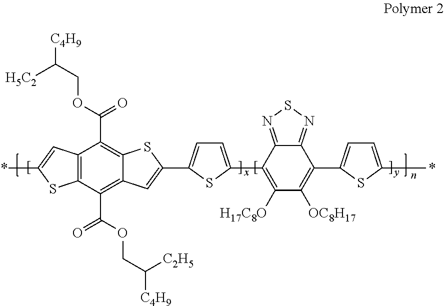

Polymer 2 is prepared according to the description of the preparation of polymer 1 as described in WO 2011/131280, example 11, pages 68 and 69. Starting materials are 2,6-dibromobenzo[1,2-b:4,5-b′]dithiophene-4,8-dicarboxylic acid di(2-ethylhexyl)ester, 2,5-bis(trimethylstannyl)thiophene and 4,7-dibromo-5,6-dioctyloxy-2,1,3-benzothiadiazole.

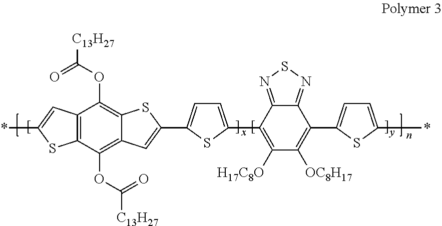

Polymer 3 and its preparation is disclosed in WO 2013/045014, example 1, pages 65 and 67.

### B) Application Examples

Perovskite solar cell (PSC) devices using comparative polymer 1 2 and 3 and polymer 1, 2 and 3 were fabricated based on the following procedures:

All the chemicals used were purchased from commercial sources unless stated otherwise.

PSC devices were fabricated based on a procedure described in N. J. Jeon et al. Nat. Mater. 13, 897 (2014). A compact TiO₂ layer was formed on a F-doped SnO₂ (1 cm² sheet resistance of 15 ohms)/glass substrate via spin coating at 2000 rpm for 30 sec from a 2-propanol solution of 0.73 g 75w % titanium diisopropoxide bis(acetylacetonate) diluted with 15 ml of butanol. The hydrothermal synthesis of TiO₂ particles was carried out with a method described in S. Ito et al. Nat. Photonics 2008, 2, 693. Thus obtained nanoparticulate TiO₂ was deposited onto the compact TiO₂ surface. The coated film was gradually heated and sintered at 500° C. for 15 min. Methylammonium iodide (MAI) was synthesised with a procedure described in J. Burschka et al., Nature 2013, 499, 316 from methylamine and an aqueous solution of hydriodic acid. 1.10 M lead iodide in dimethylformamide was spin coated on the porous TiO₂ layer, followed by an immersion into a 1M ethanol solution of MAI. Thus prepared MAPbl₃ perovskite layers were treated with toluene drop-casting and then heated at 150° C. for 2 min. The hole selecting layer was applied as followed:

### Comparative Polymers 1-3 and Polymers 1-3

A 0.21 ml toluene solution of 15 mg of polymer was spin coated on the perovskite surface at 4000 rpm for 30 sec.

Then gold was thermally evaporated on top of the hole selecting layer. The gold surface and a bare FTO surface were connected to electric wires.

Power conversion efficiency is calculated using the following expression

$$η = \frac{{V}_{oc} \times {J}_{sc} \times FF}{{P}_{i n}}$$

where FF is defined as

$$FF = \frac{{V}_{max} \times {J}_{max}}{{V}_{oc} \times {J}_{sc}}$$

PSC device characteristics for various hole selecting layer coated are shown in Table 1.

TABLE 1
Photovoltaic cell characteristics obtained under 1 sun
illumination (AM 1.5 G, 100 mW · cm⁻²).

| | Voc | Jsc | FF | PCE |
|---|---|---|---|---|
| Compound | V | mA · cm⁻² | % | % |
| Comp. polymer 1 | 0.90 | 12.3 | 64 | 7.19 |
| Comp. polymer 2 | 0.95 | 17.1 | 45 | 7.58 |
| Comp. polymer 3 | 0.91 | 16.6 | 47 | 7.16 |
| Polymer 1 | 0.95 | 17.3 | 75 | 12.7 |
| Polymer 2 | 1.02 | 16.7 | 67 | 11.4 |
| Polymer 3 | 1.01 | 16.6 | 51 | 8.53 |

It can be seen that the PSC containing polymer 1, 2 and 3 containing a BDT core substituted with an electron withdrawing group according to the invention shows a large increase in PCE over comparative polymers 1, 2 and 3.

1. Optoelectronic device comprising a light absorber which is at least in part inorganic and a polymer, oligomer or a compound comprising at least one monomeric unit according to formula (I) 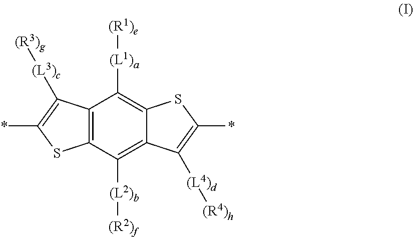
wherein
L¹⁻⁴ denote independently of each other, and on each occurrence identically or differently —C(═O)—, —C(═S)—, —C(═O)—O—, —C(═S)—O—, —C(═S)—S—, —C(═O)—S—, —O—C(═O)—, —O—C(═S)—, —C(═O)—NR⁰—, —NR⁰—C(O)—, —S(═O)(═O)—, —S(═O)(═O)—O—, —O—S(═O)(═O)—, —CF₂—, —CHF—, —CCl₂—, —CHCl—, —SF₄— or a terminal group —F, —Cl, —Br, —I, —NO₂, —SF₅, —CN, —NCO, —NCS, —OCN or —SCN in which case the respective e, f, g, h are defined as 0;
R¹⁻⁴ independently of each other denote H, halogen,
straight-chain, branched or cyclic alkyl with 1 to 40 C atoms, in which one or more non-adjacent CH₂ groups are optionally replaced by —O—, —S—, —C(O)—, —C(O)—O—, —O—C(O)—, —O—C(O)—O—, —SO₂—, —SO₃—, —NR⁰—, —SiR⁰R⁰⁰—, —CF₂—, —CR⁰═CR⁰⁰—, —CY¹═CY²— or —C≡C— in such a manner that O and/or S atoms are not linked directly to one another, and in which one or more H atoms are optionally replaced by F, Cl, Br, I or CN, or
aryl or heteroaryl having 4 to 30 ring atoms which are optionally substituted;
Y¹ and Y² independently of each other denote F, Cl or CN wherein one of Y¹ or Y² may additionally denote H;
R⁰⁻⁰⁰ independently of each other denote
alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —Si(R*)₂—, —N(R*)₂—, —CR*═CR*— or —C≡C— such that 0- and/or S-atoms are not directly linked to each other;
aryl or heteroaryl, each having from 4 to 30 ring atoms and being unsubstituted or substituted with one or more alkyl groups with 1 to 30 C atoms which are straight-chain, branched or cyclic, and which are unsubstituted or substituted with one or more F or Cl atoms or CN groups;
or denote H;
R* independently of each other, and on each occurrence identically or differently denotes F, Cl, CN, straight-chain or branched alkyl with 1 to 20 C atoms, straight-chain or branched alkoxy with 1 to 20 C atoms, straight-chain or branched oxaalkyl with 1 to 12 C-atoms, straight-chain or branched thioalkyl with 1 to 12 C atoms, straight-chain or branched fluoroalkyl with 1 to 12 C atoms and straight-chain or branched fluoroalkoxy with 1 to 12 C atoms or straight-chain or branched alkenyl with 2 to 20 C atoms;
a-h are 0 or 1 and at least either a, b, c or d is 1.

2. Device according to claim 1 which is a solar cell, an optical detector, a photoreceptor, a photodiode, a photomultiplier, a photo resistor, a photo detector, a lightsensitive detector, a solid-state triode, a transistor, an integrated circuit, a field-quench device, a light-emitting device, a laser, a laser diode, a plasmon emitting device, an electrophotography device or a wave converter.

3. Device according to claim 1 which is a solar cell.

4. Device according to claim 1 wherein the polymer, oligomer or compound comprising at least one monomeric unit according to formula (I) is employed as a layer between one electrode and the light absorber layer.

5. Device according to claim 1 wherein the polymer, oligomer or compound comprising at least one monomeric unit according to formula (I) is comprised in a hole-selective layer.

6. Device according to claim 1 wherein the polymer, oligomer or compound comprising at least one monomeric unit according to formula (I) is employed as hole transport material.

7. Device according to claim 1 wherein the polymer, oligomer or compound comprising at least one monomeric unit according to formula (I) is contained in which L¹ to L⁴ denote independently of each other, and on each occurrence identically or differently —C(═O)—, —C(═O)—O—, —O—C(═O)—, —CF₂—, or a terminal group —F, —CN in which case the respective e, f, g, h are defined as 0.

8. Device according to claim 1 wherein the polymer, oligomer or compound comprising at least one monomeric unit according to formula (I) is contained in which R¹ and R² independently of each other denote H, halogen, straight-chain, branched or cyclic alkyl with 1 to 20 C atoms, aryl or heteroaryl having 4 to 30 ring atoms which are optionally substituted one or more times by R* as defined according to claim 1.

9. Device according to claim 1 wherein the polymer, oligomer or compound comprising at least one monomeric unit according to formula (I) is contained in which R³ and R⁴ are H.

10. Device according to claim 1 wherein the polymer, oligomer or compound comprising at least one monomeric unit according to formula (I) is contained in which a, b, e, f, g and h are 1 and c and d are 0.

11. Device according to claim 1 wherein the compound or oligomer comprising at least one monomeric unit according to formula (I) correspond to formula (II)
R^{t1}-(A¹)ᵢ-(A²)ⱼ-[(A³)ₖ-(A⁴)ₗ-U-(A⁵)ₘ-(A)ₒ]_{n′}-(A⁷)ₚ-(A⁸)_{q}-R^{t2} (II)
wherein
U corresponds to formula (I) as defined according to claim 1,
A¹⁻⁸ independently of each other denote —CY^{1′}═CY^{2′}—, —C≡C—, arylene having 6 to 30 ring atoms which may be substituted by one or more groups R or heteroarylene having 5 to 30 ring atoms which may be substituted by one or more groups R, and one or more of A¹⁻⁸ may also denote U,
Y^{1′}, Y^{2′} independently of each other denote H, F, Cl or CN,
R is alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —SiR⁰R⁰⁰—, —NR⁰R⁰⁰—, —CR⁰═CR⁰⁰— or —C≡C— such that O- and/or S-atoms are not directly linked to each other;
aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
or denote H,
R^{t1, t2} independently of each other denote H, F, Cl, Br, —CN, —CF₃, R, —CF₂—R⁰, —O—R⁰, —S—R⁰, —SO₂—R, —SO³—R⁰, —C(═O)—R, —C(═S)—R, —C(═O)—CF₂—R⁰, —C(═O)—OR⁰, —C(═S)—OR⁰, —O—C(═O)—R⁰, —O—C(═S)—R⁰, —C(═O)—SR⁰, —S—C(═O)—R⁰, —C(═O)NR⁰R⁰⁰, —NR⁰—C(═O)—R⁰⁰, —NHR⁰, —NR⁰R⁰⁰, CR⁰═CR⁰⁰R⁰⁰⁰, —C≡C—R⁰, —C≡C—SiR⁰R⁰⁰R⁰⁰⁰, —SiR⁰R⁰⁰R⁰⁰⁰, —CH═C(CN)—C(O)—OR⁰, —CH═C(COOR⁰)(COOR⁰⁰), —CH═C(CONR⁰R⁰⁰)₂, —CH═C(CN)(Ar⁹), 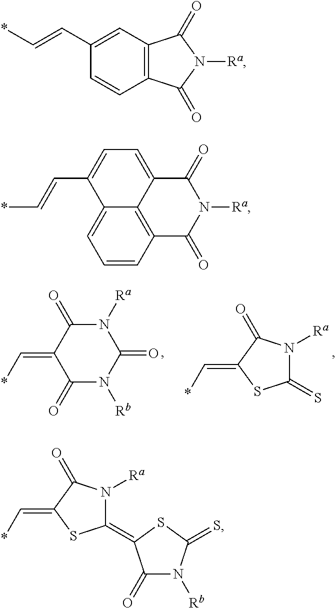
R⁰, R⁰⁰, R⁰⁰⁰ independently of each other denote
alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —Si(R*)₂—, —N(R*)₂—, —CR*═CR*— or —C≡C— such that O- and/or S-atoms are not directly linked to each other,
aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
or denote H,
R^{a}, R^{b} are independently of each other aryl or heteroaryl, each having from 4 to 30 ring atoms and being unsubstituted or substituted with one or more groups R,
R* independently of each other, and on each occurrence identically or differently denotes F, Cl, CN, straight-chain or branched alkyl with 1 to 20 C atoms, straight-chain or branched alkoxy with 1 to 20 C atoms, straight-chain or branched oxaalkyl with 1 to 12 C-atoms, straight-chain or branched thioalkyl with 1 to 12 C atoms, straight-chain or branched fluoroalkyl with 1 to 12 C atoms and straight-chain or branched fluoroalkoxy with 1 to 12 C atoms or straight-chain or branched alkenyl with 2 to 20 C atoms;
Ar⁹ is aryl or heteroaryl, each having from 5 to 30 ring atoms and being unsubstituted or substituted with one or more groups R,
i, j, k, 1, m, o, p, q are independently of each other 0 or 1, with at least one i, j, k, l, m, o, p or q being 1,
n′ is 1, 2 or 3.

12. Device according to claim 1 wherein the polymer comprising at least one monomeric unit according to formula (I) contains one or more of the repeating units corresponding to formulae (III) to (X) and the repeating units build regioregular, alternated, regiorandom, statistical, block or random homopolymer or co-polymer backbones,
*—(U)ᵤ—* (III)
*—(U)ᵤ-(A⁹)ₓ-* (IV)
*-(A⁹)ₓ-(U)ᵤ-(A¹⁰)_{y}-(A¹¹)_{z}-(A¹²)ₛ-* (V)
*—(U)ᵤ-(A⁹)ₓ-(A¹⁰)_{y}-(A¹¹)_{z}-(A¹²)ₛ-* (VI)
*-(A⁹)ₓ-(A¹⁰)_{y}-(U)ᵤ-(A¹¹)_{z}-(A¹²)ₛ-* (VII)
*—(U)ᵤ-(A⁹)ₓ-(A¹⁰)_{y}-(U)ᵥ-(A¹¹)_{z}-(A¹²)ₛ-* (VIII)
*—(U)ᵤ-(A⁹)ₓ-(U)ᵥ-(A¹⁰)_{y}-(U)_{w}-(A¹¹)_{z}-* (IX),
wherein
U corresponds to formula (I) as defined according to claim 1,
A⁹⁻¹² independently of each other denote —CY^{1′}═CY^{2′}—, —C≡C—, arylene having 6 to 30 ring atoms which may be substituted by one or more groups R or heteroarylene having 5 to 30 ring atoms which may be substituted by one or more groups R,
Y^{1′}, Y^{2′} independently of each other denote H, F, Cl or CN,
R is alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —SiR⁰R⁰⁰—, —NR⁰R⁰⁰—, —CR⁰═CR⁰⁰— or —C≡C— such that O- and/or S-atoms are not directly linked to each other,
aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
or denote H,
R⁰, R⁰⁰ independently of each other denote alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —Si(R*)₂—, —N(R*)₂—, —CR*═CR*— or —C≡C— such that O- and/or S-atoms are not directly linked to each other,
aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
or denote H,
R* independently of each other, and on each occurrence identically or differently denotes F, Cl, CN, straight-chain or branched alkyl with 1 to 20 C atoms, straight-chain or branched alkoxy with 1 to 20 C atoms, straight-chain or branched oxaalkyl with 1 to 12 C-atoms, straight-chain or branched thioalkyl with 1 to 12 C atoms, straight-chain or branched fluoroalkyl with 1 to 12 C atoms and straight-chain or branched fluoroalkoxy with 1 to 12 C atoms or straight-chain or branched alkenyl with 2 to 20 C atoms;
u, v, w are independently of each other an integer ≥1,
x, y, z, s are independently of each other and denote 0 or an integer ≥1, with at least one of x, y, z or s being ≥1.

13. Device according to claim 1 wherein the light absorber is a metal halide perovskite with the formula ABX₃, where
A is a monovalent organic cation, a metal cation or a mixture of two or more of these cations,
B is a divalent cation or a mixture of two or more of divalent cations and
X is F, Cl, Br, I or [BF₄] or a combination thereof.

14. Device according to claim 13 wherein the monovalent organic cation of the perovskite is selected from alkylammonium, wherein the alkyl group is straight-chain or branched having 1 to 6 C atoms, formamidinium or guanidinium or wherein the metal cation is selected from K⁺, Cs⁺ or Rb⁺.

15. A multijunction device comprising at least one device according to claim 1.

16. A module comprising at least one device according to claim 1.

17. A method which comprises including polymers, oligomers or compounds comprising at least one monomeric unit according to formula (I) 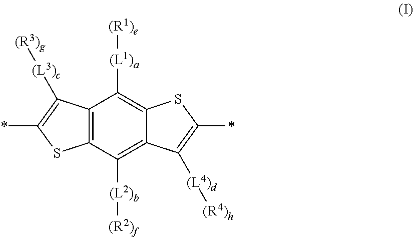
in a optoelectronic device comprising a light adsorber which is at least in part inorganic,
Wherein
L¹⁻⁴ denote independently of each other, and on each occurrence identically or differently —C(═O)—, —C(═S)—, —C(═O)—O—, —C(═S)—O—, —C(═S)—S—, —C(═O)—S—, —O—C(═O)—, —O—C(═S)—, —C(═O)—NR⁰—, —NR⁰—C(O)—, —S(═O)(═O)—, —S(═O)(═O)—O—, —O—S(═O)(═O)—, —CF₂—, —CHF—, —CCl₂—, —CHCl—, —SF₄— or a terminal group —F, —Cl, —Br, —I, —NO₂, —SF₅, —CN, —NCO, —NCS, —OCN or —SCN in which case the respective e, f, g, h are defined as 0;
R¹⁻⁴ independently of each other denote H, halogen,
straight-chain, branched or cyclic alkyl with 1 to 40 C atoms, in which one or more non-adjacent CH₂ groups are optionally replaced by —O—, —S—, —C(O)—, —C(O)—O—, —O—C(O)—, —O—C(O)—O—, —SO₂—, —SO₃—, —NR⁰—, —SiR⁰R⁰⁰—, —CF₂—, —CR⁰═CR⁰⁰—, —CY¹═CY²- or —C≡C— in such a manner that O and/or S atoms are not linked directly to one another, and in which one or more H atoms are optionally replaced by F, Cl, Br, I or CN, or
aryl or heteroaryl having 4 to 30 ring atoms which are optionally substituted;
Y¹ and Y² independently of each other denote F, Cl or CN wherein one of Y¹ or Y² may additionally denote H;
R⁰⁻⁰⁰ independently of each other denote
alkyl with 1 to 30 C atoms which is straight-chain, branched or cyclic, and is unsubstituted or substituted with one or more F or Cl atoms or CN groups, and in which one or more C atoms are optionally replaced by —O—, —S—, —C(O)—, —C(S)—, —Si(R*)₂—, —N(R*)₂—, —CR*═CR*— or —C≡C— such that O- and/or S-atoms are not directly linked to each other,
aryl or heteroaryl, each having from 4 to 30 ring atoms and being unsubstituted or substituted with one or more alkyl groups with 1 to 30 C atoms which are straight-chain, branched or cyclic, and are unsubstituted or substituted with one or more F or Cl atoms or CN groups;
or denote H;
R* independently of each other, and on each occurrence identically or differently denotes F, Cl, CN, straight-chain or branched alkyl with 1 to 20 C atoms, straight-chain or branched alkoxy with 1 to 20 C atoms, straight-chain or branched oxaalkyl with 1 to 12 C-atoms, straight-chain or branched thioalkyl with 1 to 12 C atoms, straight-chain or branched fluoroalkyl with 1 to 12 C atoms and straight-chain or branched fluoroalkoxy with 1 to 12 C atoms or straight-chain or branched alkenyl with 2 to 20 C atoms;
a-h are equal 0 or 1 and at least either a, b, c or d is 1.
